(19) United States
(12) Patent Application Publication
(10) Pub. No.: US 2024/0244820 A1
(43) Pub. Date: Jul. 18, 2024

(54) MICROELECTRONIC DEVICES, AND RELATED MEMORY DEVICES, AND ELECTRONIC SYSTEMS

(71) Applicant: Micron Technology, Inc., Boise, ID (US)

(72) Inventors: Scott E. Sills, Boise, ID (US); Si-Woo Lee`, Saratoga, CA (US); Richard E. Fackenthal, Carmichael, CA (US); Hiroki Fujisawa, Tokyo (JP)

(21) Appl. No.: 18/391,522

(22) Filed: Dec. 20, 2023

Related U.S. Application Data
(60) Provisional application No. 63/479,894, filed on Jan. 13, 2023.

(51) Int. Cl. H10B 12/00

(52) U.S. Cl. CPC H10B 12/30

(57) ABSTRACT

A microelectronic device includes memory array regions of memory cells each including a vertical stack structure comprising conductive structures vertically spaced from one another and horizontally extending through a vertical stack of memory cells. A staircase region is horizontally between two of the memory array regions horizontally neighboring one another and includes a first staircase structure horizontally extending from the vertical stack structure of a first of the two of the memory array regions and a second staircase structure horizontally extending from the vertical stack structure of a second of the two of the memory array regions. Lateral conductive contacts provide a conductive path between the first steps of the first staircase structure and the second steps of the second staircase structure. Related microelectronic devices, memory devices, and electronic systems are also described.

### CROSS-REFERENCE TO RELATED APPLICATION

This application claims the benefit under 35 U.S.C. § 119(e) of U.S. Provisional Patent Application Ser. No. 63/479,894, filed Jan. 13, 2023, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of microelectronic devices including lateral conductive contacts extending between staircase structures operatively associated with vertically stacked memory cells, and to related memory devices, and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, volatile memory devices, such as dynamic random access memory (DRAM) devices; and non-volatile memory devices such as NAND Flash memory devices. A typical memory cell of a DRAM device includes one access device, such as a transistor, and one memory storage structure, such as a capacitor. Modern applications for semiconductor devices can employ significant quantities of memory cells, arranged in memory arrays exhibiting rows and columns of the memory cells. The memory cells may be electrically accessed through digit lines (e.g., bit lines, data lines) and word lines (e.g., access lines) arranged along the rows and columns of the memory cells of the memory arrays. Memory arrays can be two-dimensional (2D) so as to exhibit a single deck (e.g., a single tier, a single level) of the memory cells, or can be three-dimensional (3D) so as to exhibit multiple decks (e.g., multiple levels, multiple tiers) of the memory cells.

As the size of the memory cells has decreased, the density and complexity of the memory array have increased. With the increased density of memory cells within the memory array, the density of the conductive interconnect structures configured to facilitate operation of the memory cells has also increased. For example, the spacing between neighboring conductive interconnect structures has decreased with the increased density of memory cells of the memory array. However, the increased density of the conductive interconnect structures presents difficulties in adequately forming conductive interconnect structures in electrical communication with the memory cells. In addition, as the density of memory cells has increased, the amount of area occupied by electrical interconnects between components of the memory cells has increased.

### BRIEF DESCRIPTION OF THE DRAWINGS

FIG. 1A through FIG. 1C are a simplified partial top-down view (FIG. 1A) and simplified partial cross-sectional views (FIG. 1B and FIG. 1C) illustrating a microelectronic device, in accordance with embodiments of the disclosure;

FIG. 1D is a simplified partial top-down view illustrating a portion of a staircase region of the microelectronic device of FIG. 1A through FIG. 1C;

FIG. 1E through FIG. 1G are simplified partial perspective views of a portion of the microelectronic device of FIG. 1A through FIG. 1C;

FIG. 1H is a simplified schematic illustrating the electrical connections between horizontally neighboring staircase structures of the microelectronic device of FIG. 1A through FIG. 1C;

FIG. 2A is a simplified partial top-down view of a microelectronic device, in accordance with embodiments of the disclosure;

FIG. 2B is a simplified partial cross-sectional view of the microelectronic device of FIG. 2A taken through section line B-B of FIG. 2A;

FIG. 2C is a partial top-down view of an enlarged portion of a staircase region of the microelectronic device of FIG. 2A;

FIG. 2D and FIG. 2F are simplified partial perspective views of a portion of the microelectronic device of FIG. 2A;

FIG. 2G is a simplified schematic illustrating the electrical connections between horizontally neighboring staircase structures of the microelectronic device of FIG. 1A;

FIG. 3A is a simplified top-down view a microelectronic device, in accordance with embodiments of the disclosure;

FIG. 3B is a simplified top-down view illustrating a portion of a staircase region of the microelectronic device of FIG. 3A;

FIG. 4 is a simplified top-down view illustrating a portion of a staircase region of a microelectronic device, in accordance with embodiments of the disclosure;

FIG. 5 is a simplified top-down view illustrating a portion of a staircase region of a microelectronic device, in accordance with additional embodiments of the disclosure;

FIG. 6 is a schematic block diagram of an electronic system, in accordance with an embodiment of the disclosure.

### DETAILED DESCRIPTION

The illustrations included herewith are not meant to be actual views of any particular systems, microelectronic structures, microelectronic devices, or integrated circuits thereof, but are merely idealized representations that are employed to describe embodiments herein. Elements and features common between figures may retain the same numerical designation except that, for ease of following the description, reference numerals begin with the number of the drawing on which the elements are introduced or most fully described.

The following description provides specific details, such as material types, material thicknesses, and processing conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete process flow for manufacturing a microelectronic device (e.g., a semiconductor device, a memory device), apparatus, or electronic system, or a complete microelectronic device, apparatus, or electronic system. The structures described below do not form a complete microelectronic device, apparatus, or electronic system. Only those process acts and structures necessary to understand the embodiments described herein are described in detail below. Additional acts to form a complete microelectronic device, apparatus, or electronic system from the structures may be performed by conventional techniques.

According to embodiments described herein, a microelectronic device includes a microelectronic device including array regions, each array region comprising vertical stacks of memory cells and vertical stack structures comprising vertically spaced conductive structures horizontally extending through the array region. The vertical stacks of memory cells individually comprise a vertical stack of storage devices, each storage device in contact with an access device of a vertical stack of access devices. The vertical stack structures horizontally terminate as staircase structures within a staircase region horizontally neighboring the array regions. Each of the array regions is horizontally neighbored by at least one staircase region. In some embodiments, each array region includes staircase structures horizontally extending from different array regions. Steps of the staircase structures are individually in contact with a conductive contact structure. The conductive contact structures of horizontally neighboring staircase structures horizontal extending from different array regions are in contact with lateral conductive contacts to electrically connect and provide a conductive path between the conductive contact structures of the horizontally neighboring staircase structures. The lateral conductive contacts horizontally extend between the staircase structures in the staircase region.

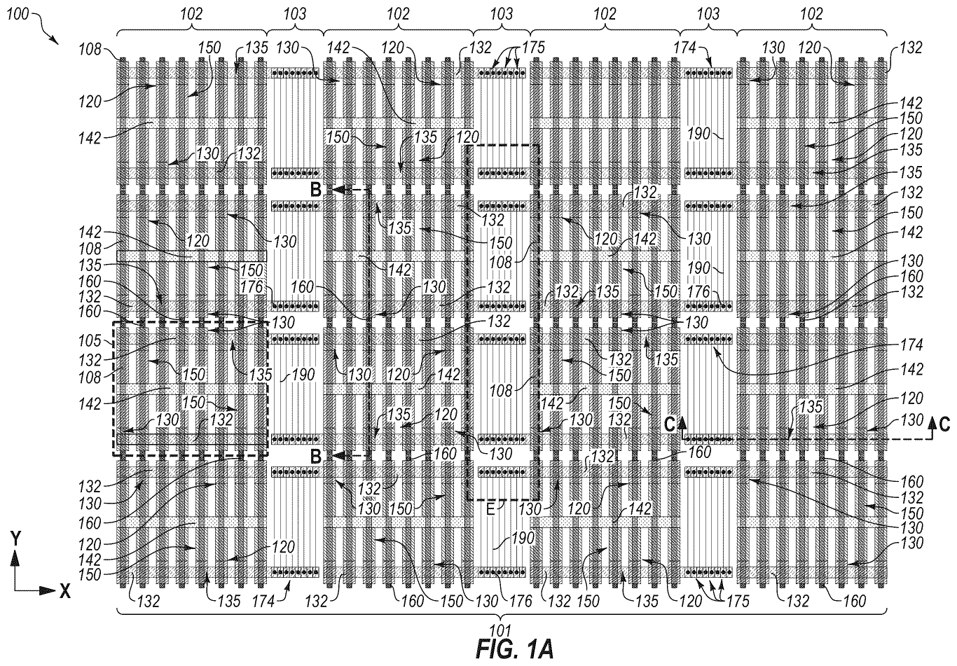

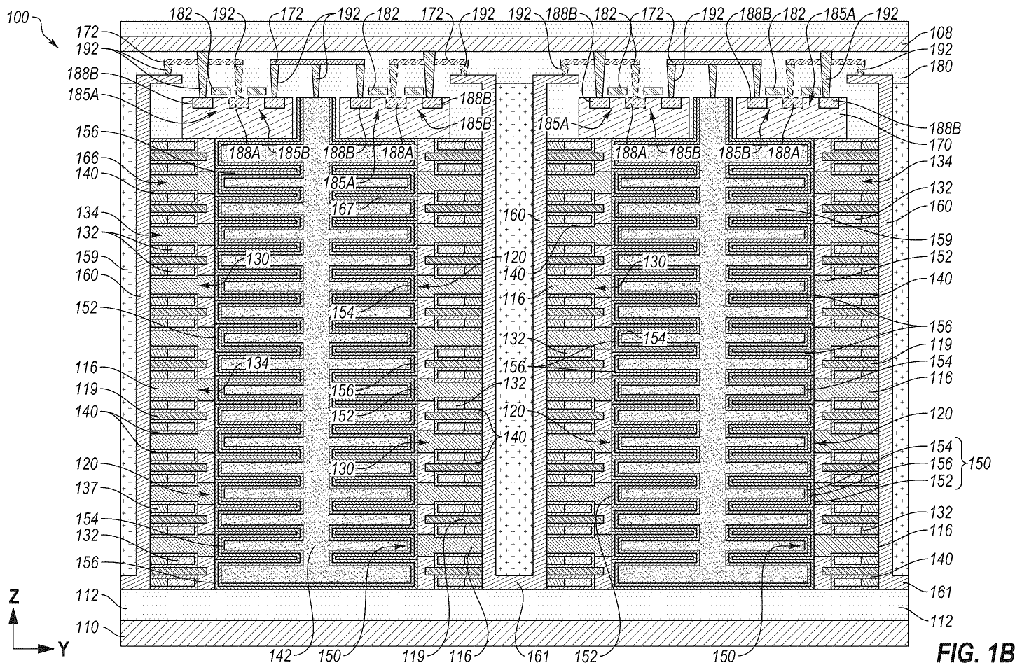

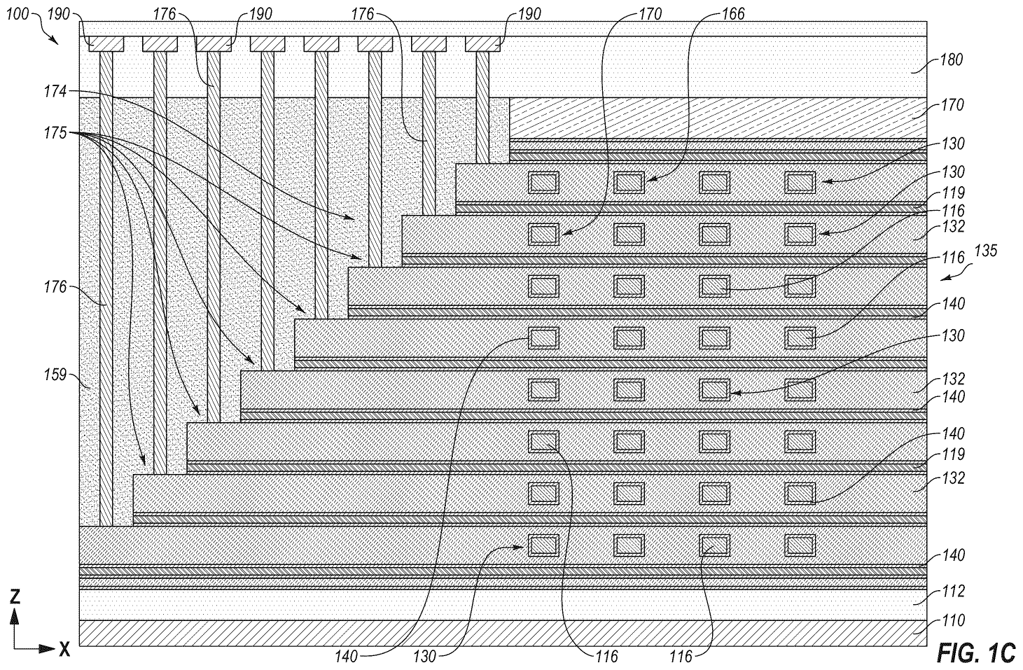

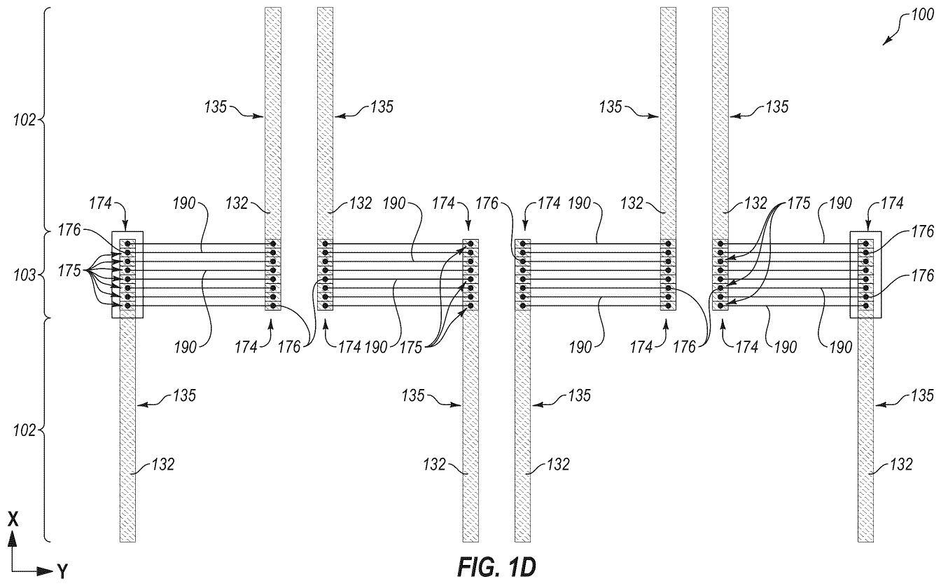

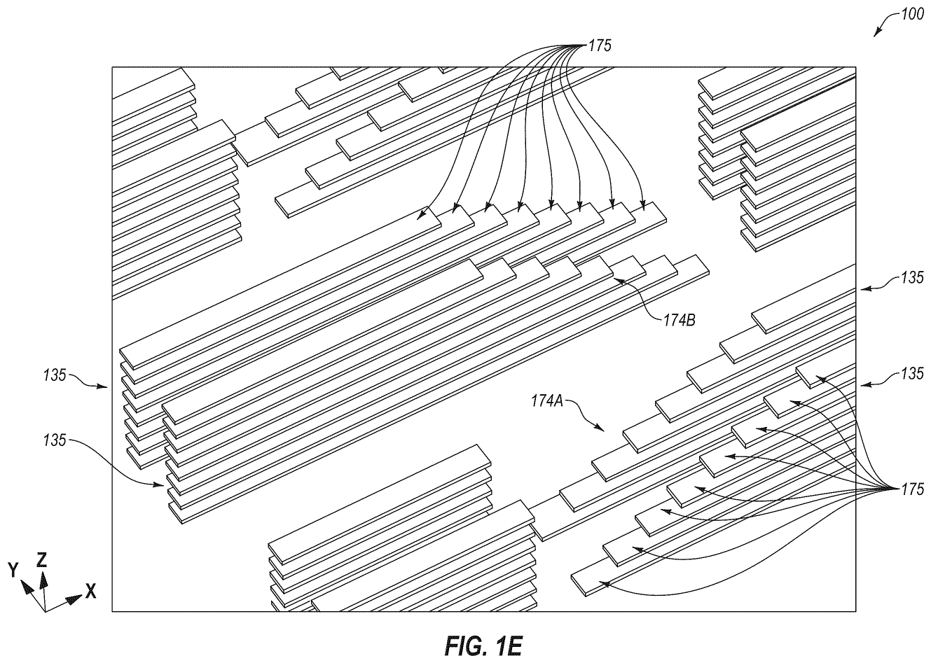

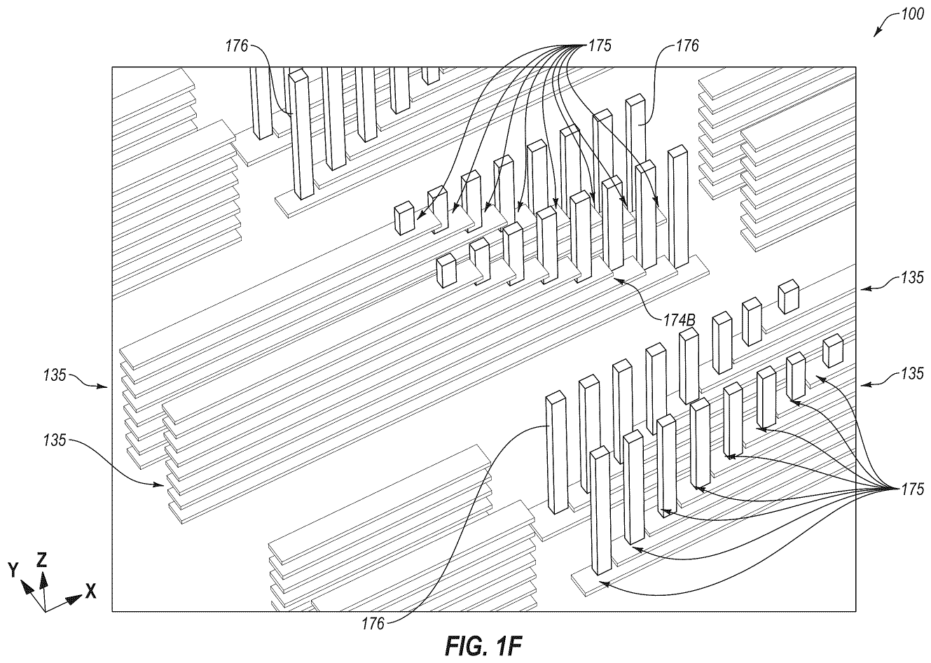

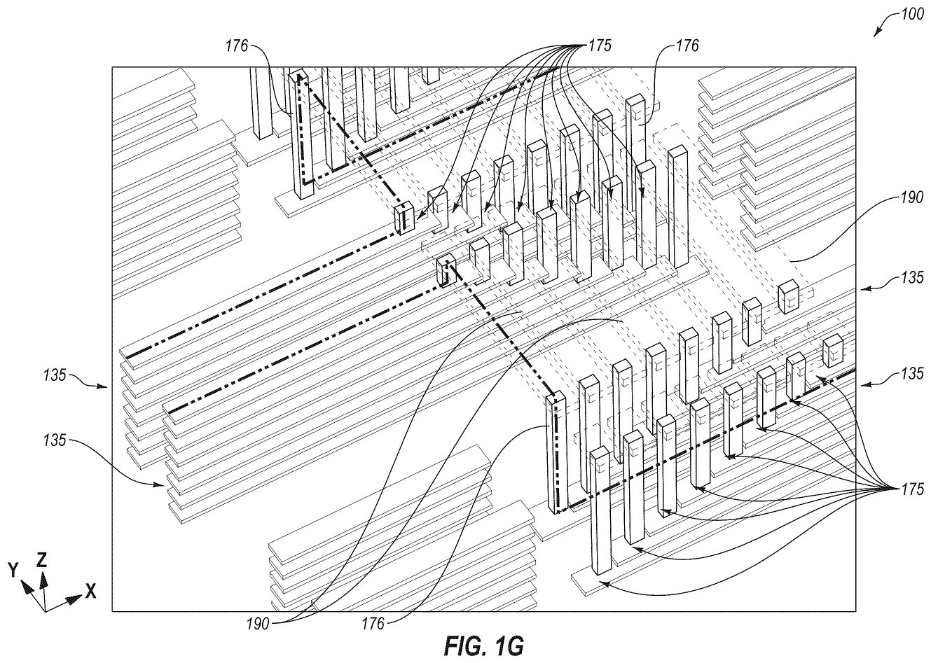

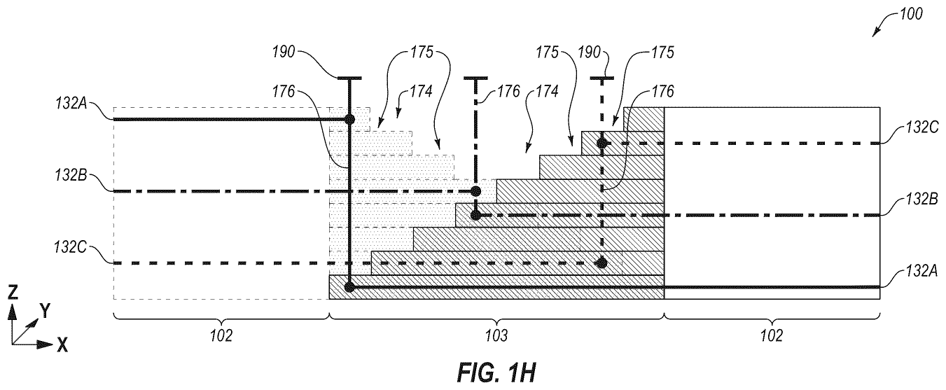

FIG. 1A through FIG. 1C are a simplified partial top-down view (FIG. 1A) and simplified partial views (FIG. 1B and FIG. 1C) of a microelectronic device 100 (e.g., a memory device, such as a 3D DRAM memory device), in accordance with embodiments of the disclosure. With the description provided below, it will be readily apparent to one of ordinary skill in the art that the structures and microelectronic devices described herein with reference to FIG. 1A through FIG. 1C may be used in various devices and electronic systems. The microelectronic device 100 may also be referred to herein as a die or a wafer.

FIG. 1A is a simplified partial top-down view of the microelectronic device 100; FIG. 1B is a simplified partial cross-sectional view of the microelectronic device 100 taken through section line B-B of FIG. 1A; and FIG. 1C is a simplified partial cross-sectional view of the microelectronic device 100 taken through section line C-C of FIG. 1A.

Referring to FIG. 1A, the microelectronic device 100 includes an array bank 101 (also referred to herein as a “memory array bank”) including array regions 102 (also referred to herein as “memory array regions”) horizontally neighboring (e.g., in the X-direction) one another and staircase regions 103 horizontally neighboring (e.g., in the X-direction) the array regions 102. In some embodiments, at least some of the staircase regions 103 are horizontally interposed between (e.g., in the X-direction) horizontally neighboring (e.g., in the X-direction) array regions 102; and at least some of the array regions 102 are horizontally interposed between (e.g., in the X-direction) horizontally neighboring (e.g., in the X-direction) staircase regions 103.

The staircase regions 103 may include staircase structures 174 including conductive contact structures 176 coupled thereto. The conductive contact structures 176 may electrically connect one or more components of the microelectronic device 100 to circuitry of a second microelectronic device or to one or more additional components (e.g., sub word line drivers).

In some embodiments, each of the staircase regions 103 exhibits about a same horizontal size (e.g., horizontal area in the XY plane) as each of the other of the staircase regions 103. In other embodiments, at least some of the staircase regions 103 have a different horizontal size than other of the staircase regions 103.

With reference to FIG. 1A and FIG. 1B, the array regions 102 of the array bank 101 individually include vertical (e.g., in the Z-direction) stacks of memory cells 120 over a base structure 110. Each vertical stack of memory cells 120 comprises a vertical stack of access devices 130 and a vertical stack of storage devices 150. The storage devices 150 of the vertical stack of storage devices 150 are coupled to the access devices 130 of the vertical stack of access devices 130. The vertical stack of access devices 130 may horizontally neighbor (e.g., in the X-direction) the vertical stack of storage devices 150. The vertical stacks of memory cells 120 may individually include vertically spaced (e.g., in the Z-direction) levels of memory cells 120, each memory cell 120 individually comprising a storage device 150 horizontally neighboring an access device 130.

With reference to FIG. 1A, each array region 102 may include sub-arrays 105, one of which is illustrated in box 105. Each sub-array 105 includes, for example, two horizontally neighboring (e.g., in the Y-direction) rows of vertical stacks of memory cells 120. In some embodiments, a conductive plate structure 142 horizontally intervenes between the two horizontally neighboring rows of vertical stacks of memory cells 120.

Global digit lines 108 (also referred to as “conductive lines,” “global bit lines,” or “bit lines”) horizontally extend (e.g., in the Y-direction) through the array regions 102 and vertically overlie (e.g., in the Z-direction) the vertical stacks of memory cells 120.

The global digit lines 108 may individually be formed of and include conductive material, such as, for example, one or more of a metal (e.g., tungsten, titanium, nickel, platinum, rhodium, ruthenium, aluminum, copper, molybdenum, iridium, silver, gold), a metal alloy, a metal-containing material (e.g., metal nitrides, metal silicides, metal carbides, metal oxides), a material including at least one of titanium nitride (TiN), tantalum nitride (TaN), tungsten nitride (WN), titanium aluminum nitride (TiAlN), iridium oxide (IrOₓ), ruthenium oxide (RuOₓ), alloys thereof, a conductively doped semiconductor material (e.g., conductively doped silicon, conductively doped germanium, conductively doped silicon germanium, etc.), polysilicon, or other materials exhibiting electrical conductivity. In some embodiments, the global digit lines 108 individually comprise tungsten. In other embodiments, the global digit lines 108 individually comprise copper.

The vertical stacks of memory cells 120 may individually include vertically spaced (e.g., in the Z-direction) levels of memory cells 120. An individual memory cell 120 may include a storage device 150 horizontally neighboring (e.g., in the Y-direction) an access device 130. Although FIG. 1A illustrates that each of the array regions 102 includes sixty-four (64) vertical stacks of memory cells 120 (e.g., eight (8) rows and eight (8) columns of the vertical stacks of memory cells 120), the disclosure is not so limited. An individual array region 102 may, for example, include greater than sixty-four vertical stacks of memory cells 120. Similarly, although FIG. 1A illustrates that each sub-array 105 includes sixteen (16) vertical stacks of memory cells 120, the disclosure is not so limited. An individual sub-array 105 may, for example, include more than sixteen (16) vertical stacks of memory cells 120, or fewer than sixteen (16) vertical stacks of memory cells 120.

The first base structure 110 may include a conventional silicon substrate (e.g., a conventional silicon wafer), or another bulk substrate comprising a semiconductive material. As used herein, the term “bulk substrate” means and includes not only silicon substrates, but also silicon-on-insulator (SOI) substrates, such as silicon-on-sapphire (SOS) substrates and silicon-on-glass (SOG) substrates, epitaxial layers of silicon on a base semiconductive foundation, and other substrates formed of and including one or more semiconductive materials (e.g., one or more of a silicon material, such monocrystalline silicon or polycrystalline silicon; silicon-germanium; germanium; gallium arsenide; a gallium nitride; and indium phosphide). In some embodiments, the first base structure 110 comprises a silicon wafer.

In some embodiments, the first base structure 110 includes different layers, structures, devices, and/or regions formed therein and/or thereon. In some embodiments, the first base structure 110 includes complementary metal-oxide-semiconductor (CMOS) circuitry and devices configured for effectuating operation of the vertical stacks of memory cells 120 of the microelectronic device 100.

With reference to FIG. 1B, the first base structure 110 may be electrically isolated from the vertical stacks of memory cells 120 by a first insulative material 112 vertically intervening (e.g., in the Z-direction) between the first base structure 110 and the vertical stacks of memory cells 120. The first insulative material 112 may be formed of and include insulative material such as, for example, one or more of an oxide material (e.g., silicon dioxide (SiO₂), phosphosilicate glass, borosilicate glass, borophosphosilicate glass, fluorosilicate glass, titanium dioxide (TiO₂), hafnium oxide (HfO₂), zirconium dioxide (ZrO₂), hafnium dioxide (HfO₂), tantalum oxide (TaO₂), magnesium oxide (MgO), aluminum oxide (Al₂O₃), or a combination thereof), and amorphous carbon. In some embodiments, the first insulative material 112 comprises silicon dioxide.

Each access device 130 of the vertical stack of access devices 130 individually includes a channel region 134 comprising channel material 116 in contact with at least a portion of the horizontally neighboring (e.g., in the Y-direction) the storage device 150 (e.g., a first electrode 152 of the horizontally neighboring storage device 150).

The channel material 116 may be formed of and include, for example, a semiconductive material (e.g., silicon). In some embodiments, the channel material 116 comprises silicon, such as epitaxially grown silicon. In some embodiments, the channel material 116 comprises a semiconductive material (e.g., polysilicon) doped with at least one N-type dopant or at least one P-type dopant. In some embodiments, at least some portions of the channel material 116 are doped with one of at least one N-type dopant (e.g., at least one of arsenic ions, phosphorous ions, and antimony ions) and at least one P-type dopant (e.g., boron ions) and at least other portions of the channel material 116 are doped with the other of the at least one N-type dopant and the at least one P-type dopant to form the channel region 134.

Each of the access devices 130 may individually be operably coupled to one or more conductive structures 132 (FIG. 1A through FIG. 1C) (also referred to herein as “first conductive lines,” “access lines,” or “word lines”). With reference to FIG. 1C, conductive structures 132 vertically overlying (e.g., in the Z-direction) and within horizontal boundaries (e.g., in the X-direction, in the Y-direction) of one another may form a vertical stack structure 135 including vertically spaced (e.g., in the Z-direction) conductive structures 132. The vertical stack structure 135 comprises levels of the conductive structures 132 vertically (e.g., in the Z-direction) spaced from one another.

With reference to FIG. 1A, each of the vertical stack structures 135 of conductive structures 132 horizontally extends (e.g., in the X-direction) through a sub-array region 105 and terminates at a staircase structure 174 located within the staircase region 103 horizontally neighboring (e.g., in the X-direction) the array region 102 through which the vertical stack structure 135 horizontally extends. In some embodiments, each sub-array 105 includes two vertical stack structures 135 horizontally extending (e.g., in the X-direction) therethrough and intersecting the vertical stack of access devices 130.

The conductive structures 132 may extend horizontally (e.g., in the X-direction; FIG. 1A) through sub-arrays 105 (e.g., through the vertical stacks of memory cells 120) as lines (e.g., word lines) and may each be configured to be operably coupled to a vertically neighboring (e.g., in the Z-direction) access device 130 (e.g., the channel region 134 of a neighboring access device 130). In other words, a conductive structure 132 may be configured to be operably coupled to a vertically neighboring access device 130. With reference to FIG. 1C, the access devices 130 may individually be located vertically between (e.g., in the Z-direction) portions of a conductive structure 132. In some embodiments, the access devices 130 are individually located vertically within (e.g., in the Z-direction) vertical boundaries of a conductive structure 132. The conductive structures 132 individually neighbor the memory cells 120 and are configured to be in electrical communication to provide a voltage to the memory cells 120, such as by means of the access devices 130. In some embodiments, the conductive structures 132 are separated from the access devices 130 by means of a dielectric material 140.

The conductive structures 132 may individually be formed of and include conductive material, such as, for example, one or more of a metal (e.g., tungsten, titanium, nickel, platinum, rhodium, ruthenium, aluminum, copper, molybdenum, iridium, silver, gold), a metal alloy, a metal-containing material (e.g., metal nitrides, metal silicides, metal carbides, metal oxides), a material including at least one of titanium nitride (TiN), tantalum nitride (TaN), tungsten nitride (WN), titanium aluminum nitride (TiAlN), iridium oxide (IrOₓ), ruthenium oxide (RuOₓ), alloys thereof, a conductively doped semiconductor material (e.g., conductively doped silicon, conductively doped germanium, conductively doped silicon germanium, etc.), polysilicon, or other materials exhibiting electrical conductivity. In some embodiments, the conductive structures 132 individually comprise tungsten. In other embodiments, the conductive structures individually comprise copper.

The conductive structures 132 may individually be configured to provide sufficient voltage to the channel region 134 directly vertically neighboring (e.g., in the Z-direction) the respective access device 130 to electrically couple a storage device 150 horizontally neighboring (e.g., in the Y-direction) and associated with the access device 130 to, for example, a conductive pillar structure (e.g., conductive pillar structure 160, also referred to as a “local digit line”) vertically extending (e.g., in the Z-direction) through or proximate the vertical stack of access devices 130 of the vertical stack of memory cells 120. Stated another way, each conductive structure 132 may individually comprise a gate structure configured to provide a sufficient voltage to the channel region 134 vertically neighboring (e.g., in the Z-direction) the conductive structure 132 to electrically couple the access device 130 including the channel region 134 to the horizontally neighboring (e.g., in the Y-direction) storage device 150.

The vertical stack structure 135 including the vertically spaced conductive structures 132 may intersect the vertical stacks of memory cells 120 of a sub-array 105, such as the vertical stacks of the access devices 130 of the vertical stacks of memory cells 120. Each of the conductive structures 132 of the vertical stack structure 135 may intersect a level (e.g., a tier) of the memory cells 120 of the vertical stack of memory cells 120. Each conductive structure 132 may intersect and comprise a portion of a plurality of vertical stacks of access devices 130 (e.g., a gate of the access devices 130).

With reference to FIG. 1A, an individual vertical stack structure 135 extends through and intersects several vertical stacks of access devices 130 of the vertical stack of memory cells 120. In some embodiments, each vertical stack structure 135 extends through horizontally neighboring (e.g., in the X-direction) vertical stacks of memory cells 120. In some embodiments, the vertical stack structures 135 extending in a first horizontal direction (e.g., in the X-direction) are spaced from each other in a second horizontal direction (e.g., in the Y-direction).

Although FIG. 1A and FIG. 1B illustrate that the conductive structures 132 of the vertical stack structure 135 individually intersect and form portions of eight (8) of the vertical stacks of memory cells 120, the disclosure is not so limited. In other embodiments, conductive structures 132 of the vertical stack structure 135 individually intersect and form portions of fewer than eight (8) of the vertical stacks of memory cells 120, such as four (4) of the vertical stacks of the memory cells 120, five (5) of the vertical stacks of the memory cells 120, or six (6) of the vertical stacks of memory cells 120. In other embodiments, the conductive structures 132 of the vertical stack structure 135 individually intersect and form portions of more than eight (8) of the vertical stacks of memory cells 120, more than ten (10) of the vertical stacks of the memory cells 120, more than twelve (12) of the vertical stacks of the memory cells 120, more than sixteen (16) of the vertical stacks of the memory cells 120, or more than twenty (20) of the vertical stacks of the memory cells 120.

In some embodiments, vertically neighboring (e.g., in the Z-direction) conductive structures 132 between vertically neighboring (e.g., in the Z-direction) access devices 130 are spaced from each other by a second insulative material 119.

The second insulative material 119 may be formed of and include an insulative material that is different than, and that has an etch selectivity with respect to, the channel material 116. In some embodiments, the second insulative material 119 is formed of and includes one or more of the materials described above with reference to the first insulative material 112. In some embodiments, the second insulative material 119 is formed of and include an oxide material (e.g., silicon dioxide).

With combined reference to FIG. 1B and FIG. 1C, each of the access devices 130 is surrounded by the dielectric material 140, which may also be referred to herein as a “gate dielectric material.” The channel region 134 is separated from the conductive structures 132 by the dielectric material 140. In other words, the conductive structures 132 are separated from the access devices 130 by the dielectric material 140. In some embodiments, the portion of the conductive structure 132 directly vertically neighboring (e.g., in the Z-direction) and located within horizontal boundaries (e.g., in the X-direction, in the Y-direction) of the dielectric material 140 may be referred to as a “gate electrode.”

In some embodiments, and as illustrated in FIG. 1C, each of the access devices 130 is substantially surrounded by the dielectric material 140 that is, in turn, substantially surrounded by the conductive structure 132. In some such embodiments, the access devices 130 may individually comprise so-called “gate all around” access devices (e.g., gate all around transistors) since each of the access devices 130 is individually substantially surrounded by one of the conductive structures 132.

The dielectric material 140 may be formed of and include insulative material. By way of non-limiting example, the dielectric material 140 may comprise one or more of phosphosilicate glass, borosilicate glass, borophosphosilicate glass (BPSG), fluorosilicate glass, silicon dioxide, titanium dioxide, zirconium dioxide, hafnium dioxide, tantalum oxide, magnesium oxide, aluminum oxide, niobium oxide, molybdenum oxide, strontium oxide, barium oxide, yttrium oxide, a nitride material (e.g., silicon nitride (Si₃N₄)), an oxynitride (e.g., silicon oxynitride), another gate dielectric material, a dielectric carbon nitride material (e.g., silicon carbon nitride (SiCN)), or a dielectric carboxynitride material (e.g., silicon carboxynitride (SiOCN)).

With continued reference to FIG. 1C, in some embodiments, the dielectric material 140 may is also located on surfaces of the conductive structures 132 and between the conductive structures 132 and the second insulative material 119. Portions of the dielectric material 140 on surfaces of the second insulative material 119 may not be referred to as a “gate dielectric” material.

With reference back to FIG. 1B, vertically neighboring (e.g., in the Z-direction) access devices 130 are spaced from one another by a third insulative material 137. In some embodiments, the third insulative material 137 surrounds at least a portion of the dielectric material 140. The third insulative material 137 may be formed of and include insulative material. In some embodiments, the third insulative material 137 comprises silicon nitride.

With reference to FIG. 1A and FIG. 1B, in some embodiments, the storage devices 150 are in contact with a conductive plate structure 142. The conductive plate structure 142 may be formed of and include conductive material, such as one or more of the materials of an electrode (e.g., a second electrode 154) of the storage devices 150. In some embodiments, the conductive plate structure 142 comprises substantially the same material composition as an electrode of the storage devices 150. In other embodiments, the conductive plate structure 142 comprises a different material composition than the electrodes of the storage devices 150. The conductive plate structures 142 may be referred to herein as “conductive plates” or “ground structures.” The conductive plate structures 142 horizontally extend (e.g., in the X-direction) as conductive plates. In some embodiments, and with reference to FIG. 1A, the conductive plate structures 142 horizontally extend in substantially the same direction and are substantially parallel to the conductive structures 132. The conductive plate structures 142 may be horizontally between (e.g., in the Y-direction) vertical stacks of memory cells 120, such as between vertical stacks of storage devices 150.

The vertical stacks of storage devices 150 vertically overlie (e.g., in the Z-direction) the base structure 110. An individual storage device 150 includes a first electrode 152 (also referred to herein as an “outer electrode,” “a first electrode plate,” or a “first node structure”), a second electrode 154 (also referred to herein as an “inner electrode,” “a second electrode plate,” or a “second node structure”), and a dielectric material 156 between the first electrode 152 and the second electrode 154. In some such embodiments, the storage devices 150 individually comprise capacitors. However, the disclosure is not so limited and in other embodiments, the storage devices 150 may individually comprise other structures, such as, for example, phase change memory (PCM), resistance random-access memory (RRAM), conductive-bridging random-access memory (conductive bridging RAM), or another structure for storing a logic state.

At least a portion of each storage device 150 is in contact with a horizontally neighboring (e.g., in the X-direction) access device 130. In some embodiments, the first electrode 152 of each storage device 150 is in contact with (and directly contacts) a horizontally neighboring access device 130.

The first electrode 152 may be formed of and include conductive material such as, for example, one or more of a metal (e.g., tungsten, titanium, nickel, platinum, rhodium, ruthenium, aluminum, copper, molybdenum, iridium, silver, gold), a metal alloy, a metal-containing material (e.g., metal nitrides, metal silicides, metal carbides, metal oxides), a material including at least one of titanium nitride (TiN), tantalum nitride (TaN), tungsten nitride (WN), titanium aluminum nitride (TiAlN), iridium oxide (IrOₓ), ruthenium oxide (RuOₓ), alloys thereof, a conductively doped semiconductor material (e.g., conductively doped silicon, conductively doped germanium, conductively doped silicon germanium), polysilicon, and other materials exhibiting electrical conductivity. In some embodiments, the first electrode 152 comprises titanium nitride.

The second electrode 154 may be formed of and include conductive material. In some embodiments, the second electrode 154 comprises one or more of the materials described above with reference to the first electrode 152. In some embodiments, the second electrode 154 comprises substantially the same material composition as the first electrode 152.

The dielectric material 156 may be formed of and include one or more of silicon dioxide (SiO₂), silicon nitride (Si₃N₄), polyimide, titanium dioxide (TiO₂), tantalum oxide (Ta₂O₅), aluminum oxide (Al₂O₃), an oxide-nitride-oxide material (e.g., silicon dioxide-silicon nitride-silicon dioxide), strontium titanate (SrTiO₃) (STO), barium titanate (BaTiO₃), hafnium oxide (HfO₂), zirconium oxide (ZrO₂), a ferroelectric material (e.g., ferroelectric hafnium oxide, ferroelectric zirconium oxide, lead zirconate titanate (PZT)), and a high-k dielectric material.

The second electrode 154 may be in contact with one of the conductive plate structures 142 of a vertical stack of memory cells 120. In some embodiments, the second electrodes 154 are substantially integral with the conductive plate structures 142. With reference to FIG. 1B, in some embodiments, the second electrodes 154 (FIG. 1B) of horizontally neighboring (e.g., in the X-direction) vertical stacks of storage devices contact the same conductive plate structure 142. In some embodiments, the conductive plate structures 142 are individually formed of conductive material, such as one or more of the materials of the second electrode 154. In some embodiments, the conductive plate structures 142 comprise substantially the same material composition as the second electrode 154. In other embodiments, the conductive plate structures 142 comprise a different material composition than the second electrode 154.

With continued reference to FIG. 1A and FIG. 1B, the microelectronic device 100 may include conductive pillar structures 160 vertically (e.g., in the Z-direction) extending through the microelectronic device 100. The conductive pillar structures 160 may also be referred to herein as “digit lines,” “second conductive lines,” “digit line pillar structures,” “local digit lines,” or “vertical digit lines.” The conductive pillar structures 160 may be electrically coupled to the access devices 130 to facilitate operation of the memory cells 120 of a vertical stack of memory cells 120. Stated another way, each conductive pillar structure 160 vertically extends directly horizontally neighboring (e.g., in the Y-direction) and in contact with access devices 130 of a vertical stack of memory cells 120. In some embodiments, each vertical stack of memory cells 120 includes one of the conductive pillar structures vertically extending (e.g., in the Z-direction) and horizontally neighboring (e.g., in the Y-direction) the vertical stack of memory cells 120 (e.g., proximate the vertical stack of access devices 130 of the memory cells 120). As described above, application of a voltage to a conductive structure 132 vertically neighboring (e.g., in the Z-direction) the channel material 116 of the channel region 134 of a vertically neighboring access device 130 may induce a current through the channel region 134 to electrically connect the conductive pillar structure 160 to the storage device 150 horizontally neighboring (e.g., in the Y-direction) the access device 130.

In some embodiments, conductive pillar structures 160 in horizontally neighboring (e.g., in the Y-direction) vertical stack structures 135 at least partially horizontally overlap (e.g., in the X-direction) one another. In some embodiments, conductive pillar structures 160 in horizontally neighboring (e.g., in the Y-direction) vertical stack structures 135 are horizontally aligned (e.g., in the X-direction) with each other. In other embodiments, conductive pillar structures 160 in horizontally neighboring (e.g., in the Y-direction) vertical stack structures 135 are horizontally offset (e.g., in the X-direction) from one another.

In some embodiments, the conductive pillar structures 160 of horizontally neighboring (e.g., in the Y-direction) vertical stacks of memory cells 120 are connected to one another through conductive portion 161 (FIG. 1B) located at a vertically lower (e.g., in the Z-direction) portion of the microelectronic device 100 (e.g., directly above the first insulative material 112). In embodiments where the conductive pillar structures 160 contact the conductive portion 161 that electrically connects horizontally neighboring (e.g., in the Y-direction) conductive pillar structures 160, the conductive pillar structures 160 may exhibit a U-shape and may be referred to as “U-shaped conductive pillar structures” or “U-shaped local digit lines.”

In other embodiments, the conductive pillar structures 160 in contact with horizontally neighboring (e.g., in the Y-direction) vertical stacks of memory cells 120 (e.g., the vertical stacks of access devices 130) are electrically isolated from one another (e.g., do not include the conductive portion 161 horizontally extending (e.g., in the Y-direction) between horizontally neighboring conductive pillar structures 160). In some embodiments, where the microelectronic device 100 does not include the conductive portions 161, horizontally neighboring (e.g., in the Y-direction) conductive pillar structures 160 may be isolated from one another and may be referred to as “I-shaped conductive pillar structures” or “I-shaped local digit lines.”

The conductive pillar structures 160 may individually be formed of and include conductive material, such as one or more of a metal (e.g., one or more of tungsten, titanium, nickel, platinum, rhodium, ruthenium, aluminum, copper, molybdenum, iridium, silver, gold), a metal alloy, a metal-containing material (e.g., metal nitrides, metal silicides, metal carbides, metal oxides), a material including at least one of titanium nitride (TiN), tantalum nitride (TaN), tungsten nitride (WN), titanium aluminum nitride (TiAlN), iridium oxide (IrOₓ), ruthenium oxide (RuOₓ), alloys thereof, a conductively doped semiconductor material (e.g., conductively doped silicon, conductively doped germanium, conductively doped silicon germanium, etc.), polysilicon, or other materials exhibiting electrical conductivity. In some embodiments, the conductive pillar structures 160 comprise tungsten.

With continued reference to FIG. 1A and FIG. 1B, in some embodiments, a semiconductive material 170 vertically overlies (e.g., in the X-direction) the vertical stacks of memory cells 120. In some embodiments, the semiconductive material 170 comprises silicon. In some embodiments, the semiconductive material 170 comprises single-crystal silicon. As described in further detail herein, the semiconductive material 170 may be used to form one or more control logic devices of the microelectronic device 100 to facilitate control operations for the memory cells 120 of the vertical stacks of memory cells 120.

Transistor structures 185 may be located within the semiconductive material 170. Each of the transistor structures 185 may each individually include conductively doped regions 188, each of which includes a source region 188A and a drain region 188B (collectively referred to herein as “conductively doped regions 188”). Channel regions of the transistor structures 185 may be horizontally interposed between the conductively doped regions 188. In some embodiments, the conductively doped regions 188 of each transistor structure 185 individually comprises one or more semiconductive materials doped with at least one conductivity enhancing chemical species, such as at least one N-type dopant (e.g., one or more of arsenic, phosphorous, antimony, and bismuth) or at least one P-type dopant (e.g., one or more of boron, aluminum, and gallium). In some embodiments, the conductively doped regions 188 comprise conductively doped silicon.

The transistor structures 185 include multiplexers 185A and additional transistors comprising so-called “bleeder” transistors 185B (also referred to as “leaker” transistors). The multiplexers 185A horizontally neighbor (e.g., in the Y-direction) the conductive pillar structures 160 and the bleeder transistors 185B horizontally neighbor (e.g., in the Y-direction) the conductive plate structures 142. The multiplexers 185A and the bleeder transistors 185B each individually comprise a gate structure 182 vertically overlying the semiconductive material 170 and horizontally extending between conductively doped regions 188. The gate structure 182 of the multiplexers 185A comprise multiplexer gates and the gate structure 182 of the bleeder transistors 185B comprise bleeder gates.

In FIG. 1B, the source regions 188A are illustrated in broken lines to indicate that the source regions 188A are located in a different plane than that of FIG. 1B. For example, the source regions 188A are horizontally offset (e.g., in the X-direction, in the Y-direction) from the drain regions 188B. In some embodiments, the drain regions 188B of the multiplexers 185A and the drain regions 188B of the bleeder transistors 185B are horizontally aligned (e.g., in the X-direction), such as with a vertically overlying (e.g., in the Z-direction) global digit line 108.

In some embodiments, each multiplexer 185A horizontally neighbors (e.g., in the X-direction, in the Y-direction) one of the bleeder transistors 185B. In some embodiments, two bleeder transistors 185B horizontally intervene (e.g., in the Y-direction) between horizontally neighboring multiplexers 185A. In some embodiments, a conductive plate structure 142 is located between horizontally neighboring (e.g., in the Y-direction) conductive pillar structures 160. Two multiplexers 185A may horizontally intervene (e.g., in the Y-direction) between the conductive pillar structures 160 and two bleeder transistors 185B may be horizontally intervene between the multiplexers 185A. In some such embodiments, the multiplexers 185A are located closer to the conductive pillar structures 160 than the bleeder transistors 185B and the bleeder transistors 185B are closer to the conductive plate structure 142 than the multiplexers 185A.

In some embodiments, the source region 188A of the multiplexer 185A is shared with the horizontally neighboring bleeder transistor 185B. Stated another way, an individual multiplexer 185A comprises a source region 188A that is shared with a source region 188A of the horizontally neighboring bleeder transistor 185B. In other words, the source region 188A of the multiplexer 185A comprises the source region 188A of the bleeder transistor 185B. The multiplexers 185A and the horizontally neighboring bleeder transistor 185B may be referred to as “shared source” transistors.

In some embodiments, each of the source regions 188A and the drain regions 188B are individually in contact with first conductive interconnect structures 192. The first conductive interconnect structures 192 in contact with the source regions 188A and the conductive pillar structures 160 may electrically connect the source regions 188A of the multiplexers 185A to the conductive pillar structures 160 by means of a routing structure 172. The first conductive interconnect structures 192 in contact with the drain regions 188B of the multiplexers 185A may electrically connect the drain region 188B of the multiplexers 185A to the global digit line 108. In some embodiments, the first conductive interconnect structure 192 electrically connecting the multiplexer 185A to the global digit line 108 may be referred to as a “global digit line contact structure.”

In some embodiments, the first conductive interconnect structure 192 in contact with the drain regions 188B of the bleeder transistors 185B and in contact with the conductive plate structure 142 electrically connect the bleeder transistors 185B to the conductive plate structure 142 by means of routing structures 172.

The multiplexers 185A may be configured to selectively place the vertical stacks of memory cells 120 in electrical communication with a global digit line 108 by means of the first conductive interconnect structure 192 electrically connecting the multiplexer 185A to the global digit line 108. By way of non-limiting example, a select voltage may be applied to the gate structure 182 of the multiplexer 185A to electrically connect the global digit line 108 to a vertical stack of memory cells 120 associated with the multiplexer 185A. Application of the select voltage to the gate structure 182 of the multiplexer 185A may place the conductive pillar structure 160 of the selected vertical stack of memory cells 120 in electrical communication with the global digit line 108 in electrical communication with the conductive pillar structure 160. Accordingly, the conductive pillar structure 160 (e.g., the local digit line) of each vertical stack of memory cells 120 may selectively be coupled to the global digit line 108 by means of the multiplexer 185A between the conductive pillar structure 160 and the global digit line 108.

Each global digit line 108 may be configured to be selectively coupled to more than one of the conductive pillar structures 160 by means of the multiplexers 185A coupled to global digit lines 108. Each of the conductive pillar structures 160 is configured to be in electrical communication with the global digit line 108 and one of the multiplexers 185A by means of the first conductive interconnect structure 192 in contact with the global digit line 108 and the multiplexer 185A in electrical communication with the conductive pillar structure 160. In some embodiments, each global digit line 108 is configured to selectively be in electrical communication with four (4) of the conductive pillar structures 160, each one of which is associated with a vertical stack of memory cells 120. In other embodiments, each of the global digit lines 108 is configured to selectively be in electrical communication with eight (8) of the conductive pillar structures 160 or sixteen (16) of the conductive pillar structures 160. In use and operation, application of a voltage to the gate structure 182 of the multiplexer 185A induces a current in the channel region of the multiplexer 185A and electrically connects the global digit line 108 (e.g., by means of the first conductive interconnect structure 192, the routing structure 172, and the drain region 188B of the multiplexer 185A) to the conductive pillar structure 160 (e.g., by means of the source region 188A of the multiplexer 185A, the first conductive interconnect structure 192 in contact with the source region 188A, and the routing structure 172). Accordingly, in some embodiments, the multiplexers 185A are individually configured to receive a signal (e.g., a select signal) from a multiplexer driver and provide the signal to a bit line (e.g., conductive pillar structures 160 (FIG. 1B)) to selectively access desired memory cells 120 within the array bank 101 for effectuating one or more control operations of the memory cells 120.

The bleeder transistors 185B may individually be configured to provide a bias voltage to the conductive pillar structures 160 to which it is coupled. In some embodiments, the conductive plate structure 142 coupled to the bleeder transistors 185B are configured to receive a voltage, such as a drain voltage V_{dd} or a voltage source supply Vₛₛ, during use and operation. In use and operation, the bleeder transistors 185B are configured to provide a negative voltage to the conductive pillar structures 160 of unselected (e.g., inactive) vertical stacks of memory cells 120. In other words, the bleeder transistors 185B are configured to electrically connect unselected conductive pillar structures 160 with their respective conductive plate structures 142 (e.g., ground structures, cell plates), which may be coupled to a negative voltage. In some embodiments, each vertical stack of memory cells 120 includes at least one (e.g., one) of the multiplexers 185A and at least one (e.g., one) of the bleeder transistors 185B.

The gate structures 182, the first conductive interconnect structures 192, and the routing structures 172 may individually be formed of and include conductive material, such as one or more of tungsten, copper, and aluminum.

The gate structures 182, the first conductive interconnect structures 192, and the routing structures 172 may individually be formed in a fourth insulative material 180. The fourth insulative material 180 may include one or more of the materials described above with reference to the first insulative material 112. In some embodiments, the fourth insulative material 180 comprises silicon dioxide.

With collective reference to FIG. 1A and FIG. 1C, the conductive structures 132 of the vertical stack structure 135 may horizontally (e.g., in the X-direction) terminate at the staircase structures 174 located at horizontally (e.g., in the X-direction) terminal portions (e.g., ends) of the vertical stack structure 135. The staircase structures 174 may be located within the staircase regions 103 horizontally neighboring (e.g., in the X-direction) the array regions 102. Thus, the vertical stack structures 135 may include portions horizontally extending (e.g., in the X-direction) through the array region 102 and portions (e.g., the staircase structures 174) horizontally extending (e.g., in the X-direction) from the array region 102 and into the staircase region 103. While the staircase structures 174 are illustrated in FIG. 1A, it will be understood that the staircase structures 174 are located beneath a vertically upper (e.g., in the Z-direction) surface of the microelectronic device 100. With reference to FIG. 1C, vertically higher (e.g., in the Z-direction) conductive structures 132 may have a smaller horizontal dimension (e.g., in the X-direction) than vertically lower conductive structures 132, such that horizontal edges (e.g., in the X-direction) of the conductive structures 132 at least partially define steps 175 of the staircase structures 174. In some embodiments, the memory cells 120 of the vertical stack of memory cells 120 that are vertically higher (e.g., in the Z-direction) than other memory cells 120 comprise are intersected by conductive structures 132 having a smaller horizontal dimension (e.g., in the X-direction) than conductive structures 132 of vertically lower memory cells 120 of the vertical stacks of memory cells 120.

In some embodiments, the vertical stack structures 135 may each individually include one staircase structure 174 at only one horizontal end (e.g., in the X-direction) of the vertical stack structure 135. In some embodiments, each sub-array 105 includes two vertical stack structures 135 of conductive structures 132 horizontally spaced (e.g., in the Y-direction) from one another. In some embodiments, the staircase structures 174 of the vertical stack structures 135 of conductive structures 132 of the same sub-array 105 may be located at opposing horizontal ends (e.g., in the X-direction) of the microelectronic device 100. In some such embodiments, half of the vertical stack structures 135 of conductive structures 132 (e.g., in the Y-direction) include a staircase structure 174 at a first horizontal end (e.g., in the X-direction) of the respective vertical stack structure 135 while the other vertical stack structures 135 of conductive structures 132 individually include a staircase structure 174 at a second horizontal end (e.g., in the X-direction) opposite the first horizontal end of the respective other vertical stack structure 135. In some embodiments, horizontally neighboring (e.g., in the Y-direction) vertical stack structures 135 of horizontally neighboring (e.g., in the Y-direction) sub-arrays 105 may be located at the same horizontal end (e.g., in the X-direction) of the respective sub-arrays 105.

With reference to FIG. 1A, in some embodiments, the staircase structures 174 horizontally overlap (e.g., in the X-direction) one another. In some embodiments, at least a portion of an individual staircase structures 174 does not horizontally overlap (e.g., in the X-direction) at least a portion of another staircase structures 174. In some embodiments, the staircase structures 174 horizontally extending from a stack structure 135 of a sub-array 105 are horizontally offset from one another in a first horizontal direction (e.g., in the X-direction) and in a second horizontal direction (e.g., in the Y-direction). For example, with reference to FIG. 1A, in some embodiments, a first staircase structure 174 horizontally extending (e.g., in the X-direction) from a sub-array 105 horizontally extends (e.g., in the X-direction) into a first staircase region 103 and a second staircase structure 174 horizontally extending (e.g., in the X-direction) from the sub-array 105 horizontally extends (e.g., in the X-direction) into a second staircase region 103 horizontally neighboring (e.g., in the X-direction) the first staircase region 103.

The quantity of the steps 175 may correspond to the quantity of the levels of memory cells 120 of the vertical stack. In some embodiments, a quantity of the steps 175 of the staircase structures 174 equals the number of levels of memory cells 120 of the vertical stack of memory cells 120. Although FIG. 1A and FIG. 1C illustrate that the staircase structures 174 individually comprise a particular number (e.g., eight (8)) steps 175, the disclosure is not so limited. In other embodiments, the staircase structures 174 individually include a quantity of steps 175 within a range from thirty-two (32) of the steps 175 to two hundred fifty-six (256) of the steps 175. In some embodiments, the staircase structures 174 individually include sixty-four (64) of the steps 175. In other embodiments, the staircase structures 174 individually include ninety-six (96) or more of the steps 175. In some such embodiments, an individual vertical stack of memory cells 120 of the microelectronic device 100 includes a corresponding quantity of memory cells 120. In other embodiments, the staircase structures 174 individually include a different number of the steps 175, such as less than sixty-four (64) of the steps 175 (e.g., less than or equal to sixty (60) of the steps 175, less than or equal to fifty (50) of the steps 175, less than about forty (40) of the steps 175, less than or equal to thirty (30) of the steps 175, less than or equal to twenty (20) of the steps 175, less than or equal to ten (10) of the steps 175); or greater than sixty-four (64) of the steps 175 (e.g., greater than or equal to seventy (70) of the steps 175, greater than or equal to one hundred (100) of the steps 175, greater than or equal to about one hundred twenty-eight (128) of the steps 175, greater than two hundred fifty-six (256) of the steps 175).

In some embodiments, the staircase structures 174 individually include the same quantity of the steps 175. In some embodiments, each step 175 of each staircase structure 174 may be vertically offset (e.g., in the Z-direction) from a vertically neighboring step 175 of the staircase structure 174 by one level (e.g., one tier) of the vertically alternating conductive structures 132 and the vertically intervening (e.g., in the Z-direction) dielectric material 140 and second insulative material 119. In some such embodiments, every conductive structure 132 of the vertical stack structure 135 comprises a step 175 at a horizontal end (e.g., in the X-direction) of the staircase structures 174 of the vertical stack structure 135.

With continued reference to FIG. 1A and FIG. 1C, conductive contact structures 176 may contact individual conductive structures 132 at the steps 175. For example, the conductive contact structures 176 may individually physically contact (e.g., land on) portions of upper surfaces of the conductive structures 132 at least partially defining treads of the steps 175. Thus, in each step 175 may be contact with a conductive contact structure 176 at the horizontal (e.g., in the X-direction) end of the staircase structure 174.

Lateral conductive contacts 190 may vertically overlie and individually contact the conductive contact structures 176. Each of the conductive contact structures 176 may individually contact one of the lateral conductive contacts 190. The lateral conductive contacts 190 may be formed within the fourth insulative material 180.

The conductive contact structures 176 and the lateral conductive contacts 190 may individually be formed of and include conductive material, such as one or more of the materials described above with reference to the conductive pillar structures 160. In some embodiments, the conductive contact structures 176 and the lateral conductive contacts 190 individually comprise substantially the same material composition as the conductive pillar structures 160. In other embodiments, the conductive contact structures 176 and the lateral conductive contacts 190 individually comprise a different material composition than the conductive pillar structures 160. In some embodiments, the conductive contact structures 176 and the lateral conductive contacts 190 individually comprise tungsten.

With continued reference to FIG. 1C, a fifth insulative material 159 may vertically overlie (e.g., in the Z-direction) the staircase structures 174. The fifth insulative material 159 may be formed of and include insulative material, such as one or more of the materials described above with reference to the first insulative material 112. In some embodiments, the fifth insulative material 159 comprises silicon dioxide.

With reference to FIG. 1A, the lateral conductive contacts 190 may horizontally extend (e.g., in the Y-direction) between the conductive contact structures 176 of horizontally neighboring (e.g., in the Y-direction) staircase structures 174. FIG. 1D is an enlarged portion of one of one of the staircase regions 103 and illustrates the staircase structures 174 of the vertical stack structures 135 and portions of the vertical stack structures 135 horizontally extending (e.g., in the X-direction) into the staircase region 103 from the array regions 102 horizontally neighboring (e.g., in the X-direction) the staircase region 103. FIG. 1E is a simplified perspective view illustrating box E of FIG. 1A, but not showing the lateral conductive contacts 190 or the conductive contact structures 176. FIG. 1F is a simplified perspective view illustrating the same view of FIG. 1E, and including the conductive contact structures 176 and not the lateral conductive contacts 190. FIG. 1G is a simplified perspective view illustrating the same view of FIG. 1E including the conductive contact structures 176 and the lateral conductive contacts 190. The lateral conductive contacts 190 are illustrated in broken lines in FIG. 1G for clarity and ease of understanding the relative location of the lateral conductive contacts 190 with respect to the conductive contact structures 176 and the staircase structures 174. For clarity and ease of understanding the description, FIG. 1D through FIG. 1G do not illustrate other components of the microelectronic device 100, such as the vertical stacks of memory cell 120 within the array regions 102.

With reference to FIG. 1A, FIG. 1C, and FIG. 1E through FIG. 1G, and as previously described, the horizontal dimension (e.g., in the X-direction) of the conductive structures 132 may decrease with an increasing vertical height (e.g., in the Z-direction) of the step 175 vertically above the base structure 110. In some embodiments, the steps 175 of the staircase structures 174 vertically descend (e.g., in the Z-direction) in a horizontal direction (e.g., in the X-direction) away from the array region 102 through which the vertical stack structure 135 extends.

Each staircase structure 174 may exhibit a positive slope or a negative slope. In some embodiments, a phantom line extending from a top of each of half of the staircase structures to a bottom of the staircase structures 174 may have a positive slope, and another phantom line extending from a top of the other half of the staircase structures 174 to a bottom of the staircase structures 174 may have a negative slope. For example, with reference to FIG. 1E, staircase structure 174A may exhibit a positive slope and staircase structure 174B may exhibit a negative slope. In some embodiments, the positive slope and the negative slope have the same magnitude (e.g., the positive slope may be X, and the negative slope may be −X, where X is a number corresponding to the change in the vertical dimension (e.g., in the Z-direction) divided by the change in the horizontal dimension (e.g., in the X-direction) of the staircase structure 174).

With reference back to FIG. 1A, a positive X-direction may be defined as the direction extending to the right in the view of FIG. 1A and a negative X-direction may be defined as opposite the positive X-direction (e.g., extending to the left in the view of FIG. 1A). In some embodiments, staircase structures 174 that are operatively associated with vertical stack structures 135 of the same sub-array 105 (e.g., including conductive structures 132 horizontally extending (e.g., in the X-direction) through the same sub-array 105) are located in different staircase regions 103 and exhibit a different slope. For example, each sub-array 105 may be operatively associated with one staircase structure 174 having a positive slope and one staircase structure 174 having a negative slope.

In some embodiments, at least some of the staircase structures 174 exhibit the same slope (e.g., descend in the same horizontal direction (e.g., in the X-direction)) as a horizontally nearest (e.g., in the Y-direction) staircase structure 174 (other than horizontally terminal (e.g., in the Y-direction) staircase structures 174). Within a particular staircase region 103, staircase structures 174 exhibiting the same slope (e.g., the same negative slope or the same positive slope) may horizontally extend (e.g., in the X-direction) from the same array region 102 and staircase structures 174 exhibiting a different slope (e.g., the opposite slope) may horizontally extend (e.g., in the X-direction) from a different array region 102. In some embodiments, each staircase structure 174 may be located a horizontally nearest (e.g., in the Y-direction) staircase structure 174 including conductive structures 132 horizontally extending (e.g., in the X-direction) through the same array region 102 as the conductive structures 132 of the staircase structure 174. A staircase structure 174 on a horizontal side of the staircase structure 174 opposite the horizontally nearest (e.g., in the Y-direction) staircase structure 174 may include conductive structures 132 horizontally extending (e.g., in the X-direction) through a different array region 102 than the conductive structures 132 of the staircase structure 174.

In some embodiments, an individual the staircase structures 174 is horizontally interposed between (e.g., in the Y-direction) another staircase structure 174 exhibiting the same slope as the staircase structure 174 and an additional staircase structures 174 exhibiting different (e.g., opposite) slope than the staircase structure 174.

With reference to FIG. 1A and FIG. 1G, a conductive path connects the lateral conductive contacts 190 with portions of the conductive structures 132 defining the steps 175 by means of the conductive contact structures 176. In some embodiments, a conductive path extends from an individual lateral conductive contact 190 through an individual conductive structure 132 at an individual step 175 of a first staircase structure 174 by way of a conductive contact structure 176 vertically overlying (e.g., in the Z-direction) and horizontally overlapping (e.g., in the X-direction, in the Y-direction) a portion of the conductive structure 132 defining the step 175. The conductive path also operably couples the conductive structure 132 of the first staircase structure 174 with another individual conductive structure 132 at an individual step 175 of another staircase structure 174 by way of another conductive contact structure 176 vertically overlying (e.g., in the Z-direction) and horizontally overlapping (e.g., in the X-direction, in the Y-direction) a portion of the another conductive structure 132 defining the another step 175. The lateral conductive contacts 190 may each individually exhibit substantially the same horizontal length (e.g., in the Y-direction) as one another.

With collective reference to FIG. 1A and FIG. 1D through FIG. 1G, the steps 175 staircase structures 174 horizontally neighboring one another in the Y-direction may horizontally overlap one another (e.g., may be substantially horizontally aligned) in the X-direction. In some such embodiments, the lateral conductive contacts 190 extend in in the Y-direction between the staircase structures 174 horizontally neighboring one another in the Y-direction. In some embodiments, a vertically highest (e.g., in the Z-direction) step 175 of a first staircase structure 174 sharing a lateral conductive contact 190 with a second staircase structure 174 is substantially laterally aligned (e.g., in the X-direction) with a vertically lowest (e.g., in the Z-direction) step 175 of the second staircase structure 174. A second vertically highest (e.g., in the Z-direction) step 175 of the first staircase structure 174 may be substantially laterally aligned (e.g., in the X-direction) with the second vertically lowest (e.g., in the Z-direction) step 175 of the second staircase structure 174. The lateral alignment (e.g., in the X-direction) of the steps 175 of the first staircase structure 174 and the second staircase structure 174 continues such that a vertically lowest (e.g., in the Z-direction) step 175 of the first staircase structure 174 is substantially laterally aligned (e.g., in the X-direction) with a vertically highest (e.g., in the Z-direction) step 175 of the second staircase structure 174.

Accordingly, if each staircase structure 174 includes n steps 175, the n^{th} step 175 of and individual staircase structure 174 may comprise a highest step 175 horizontally nearest in the X-direction to the array region 102 from which the staircase structure 174 extends, and the first step 175 may comprise a lowest step 175 horizontally farthest in the X-direction from the array region 102 from which it extends. In some embodiments, a conductive path operably couples the n^{th} step 175 of one of the staircase structures 174 with the first step 175 of another one of the staircase structures 174 by means of a first of the lateral conductive contacts 190; a conductive path operably couples the n−1 step 175 of the one of the staircase structures 174 with the second step 175 of the another one of the staircase structures 174 by means of a second of the lateral conductive contacts 190; a conductive path operably couples the n−2 step 175 of the one of the staircase structure 174 with the third step 175 of the another one of the staircase structures 174 by means of a third of the lateral conductive contacts 190; and the conductive paths between steps 175 of the one of the staircase structures 174 and the steps 175 of another one of the staircase structures 174 continues until the first step 175 of the one of the staircase structures 174 operably coupled with the n^{th} step 175 of the another one of the staircase structures 174.

In some embodiments, a conductive path operably couples the steps 175 of each staircase structure 174 in electrical communication with steps 175 of another staircase structure 174 exhibiting a different (e.g., an opposite) slope than the staircase structure 174 by means of the lateral conductive contacts 190. In some embodiments, two of the staircase structures 174 horizontally extending in the X-direction from two different array regions 102 than one another that are configured to be in electrical communication with one another by means of a group of the lateral conductive contacts 190 horizontally extending in the Y-direction through one of the staircase regions 103 horizontally interposed between the two different array regions 102 in the X-direction. In some embodiments, the conductive structures 132 of steps 175 of some staircase structures 174 exhibiting the same slope as one another may individually horizontally extend in the X-direction away from vertical stack structures 135 horizontally extending (e.g., in the X-direction) into a first array region 102, and may individually be configured to be in electrical communication with conductive structures 132 of steps 175 of another staircase structure 174 exhibiting a different slope and horizontally extending in the X-direction away from a vertical stack structure 135 within a second array region 102 horizontally neighboring the first array region 102 in the X-direction. In some embodiments, the steps 175 of an individual staircase structure 174 defined by edges of an individual vertical stack structure 135 horizontally extending (e.g., in the X-direction) through a first array region 102 are configured to be in electrical communication with the steps 175 of a horizontally nearest (e.g., in the X-direction, in the Y-direction) staircase structure 174 defined by edges of another vertical stack structure 135 horizontally extending (e.g., in the X-direction) through a second array region 102 by means of the lateral conductive contacts 190.

In some embodiments, within an individual staircase region 103, the staircase structures 174 are staggered from one another (e.g., offset from one another in the Y-direction). In some such embodiments, pairs of the staircase structures 174 in electrical communication with the same group of lateral conductive contacts 190 are offset from one another in a horizontal direction (e.g., in the Y-direction). In other words, pairs of the staircase structures 174 sharing conductive paths between the conductive structures 132 by means of the same group of lateral conductive contacts 190 are offset from one another in a horizontal direction (e.g., in the Y-direction).

With reference to FIG. 1G, a conductive path between a conductive structure 132 defining the first step 175 of a first staircase structure 174 and a conductive structure 132 defining the n^{th} step 175 of a second conductive staircase structure 174 is illustrated in a dashed line to illustrate how horizontally neighboring (e.g., in the Y-direction) staircase structures 174 of horizontally neighboring array regions 102 are electrically connected by means of the lateral conductive contacts 190.

With continued reference to FIG. 1G, in some embodiments, the lateral conductive contacts 190 individually exhibit substantially the same vertical position (e.g., in the Z-direction) as one another.

FIG. 1H is a simplified schematic illustrating electrical connections between horizontally neighboring (e.g., in the Y-direction) staircase structures 174 of sub-arrays 105 of horizontally neighboring (e.g., in the X-direction) array regions 102. In the view of FIG. 1H, the Y-direction is in and out of the page. Accordingly, a first staircase structure 174 (e.g., the staircase structure 174 on the left) is illustrated in broken lines to indicate that it is located in a different plane than a second staircase structure 174. FIG. 1H illustrates only some of the conductive structures 132 for clarity and ease of understanding the description. With reference to FIG. 1H, conductive structures 132A, 132B, 132C partially defining a first staircase structure 174 share a conductive path with conductive structures 132A, 132B, 132C partially defining a second staircase structure 174 by means of the lateral conductive contacts 190. FIG. 1H illustrates how the conductive structures 132A, 132B, 132C partially defining the first staircase structure 174 individually share respective conductive paths (e.g., are individually in electrical communication) with corresponding conductive structures 132A, 132B, 132C partially defining the second staircase structure 174 based on the vertical height (e.g., in the Z-direction) of the conductive structures 132A, 132B, 132C of the two staircase structures 174.

With reference to FIG. 1E through FIG. 1H, the conductive structures 132 of vertically lowermost (e.g., in the Z-direction) steps 175 (e.g., a vertically lowermost half of the steps 175) of the staircase structures 174 extending from horizontally neighboring (e.g., in the X-direction) array regions 102 may horizontally overlap (e.g., in the X-direction) one another. In other words, the conductive structures of the vertically lowermost steps 175 of the staircase structures 174 extending from horizontally neighboring (e.g., in the X-direction) array regions 102 may be located within horizontal boundaries (e.g., in the X-direction) of one another. In some embodiments, the conductive structures 132 of the vertically uppermost (e.g., in the Z-direction) steps 175 (e.g., the vertically uppermost half of the steps 175) of the staircase structures 174 extending from horizontally neighboring (e.g., in the X-direction) array regions 102 may not horizontally overlap (e.g., in the X-direction) one another. In other words, the conductive structures 132 of the vertically uppermost steps 175 of the staircase structures 174 extending from horizontally neighboring (e.g., in the X-direction) array regions 102 may be located outside of horizontal boundaries (e.g., in the X-direction) of one another.

Forming the microelectronic device 100 to include the staircase regions 103 including staircase structures 174 horizontally extending away from (e.g., in the positive X-direction) a first array region 102 electrically connected to staircase structures 174 horizontally extending away from (e.g., in the negative X-direction) a second array region 102 by means of the lateral conductive contacts 190 facilities reducing an area of the microelectronic device 100 occupied by conductive interconnects and conductive routing for the steps 175 of the staircase structures 174 (e.g., to electrically connect the conductive structures 132 to one or more devices, such as to provide an access voltage to the access devices 130).

The lateral conductive contacts 190 may each individually be configured to be in electrical communication with one or more other devices. In some embodiments, the lateral conductive contacts 190 are individually configured to be in electrical communication with a sub word line driver device. In some such embodiments, the conductive structures 132 partially defining the steps 175 of staircase structures 174 coupled to one another by way of the lateral conductive contact 190 and the conductive contact structures 176 are configured to be in electrical communication with the same sub word line drivers.

Electrically connecting the conductive structures 132 defining relatively vertically higher (e.g., in the Z-direction) steps 175 of a first staircase structure 174 to the conductive structures 132 defining relatively vertically lower (e.g., in the Z-direction) steps 175 of a second staircase structure 174 facilitates forming the conductive structures 132 to exhibit the same loading (e.g., the same word line loading) during use and operation of the microelectronic device 100. For example, during accessing of the memory cells 120 electrically connected to the conductive structures 132, the conductive structures 132 may each individually exhibit substantially the same load due to the electrical connections extending between the first staircase structure 174 and the second staircase structure 174.

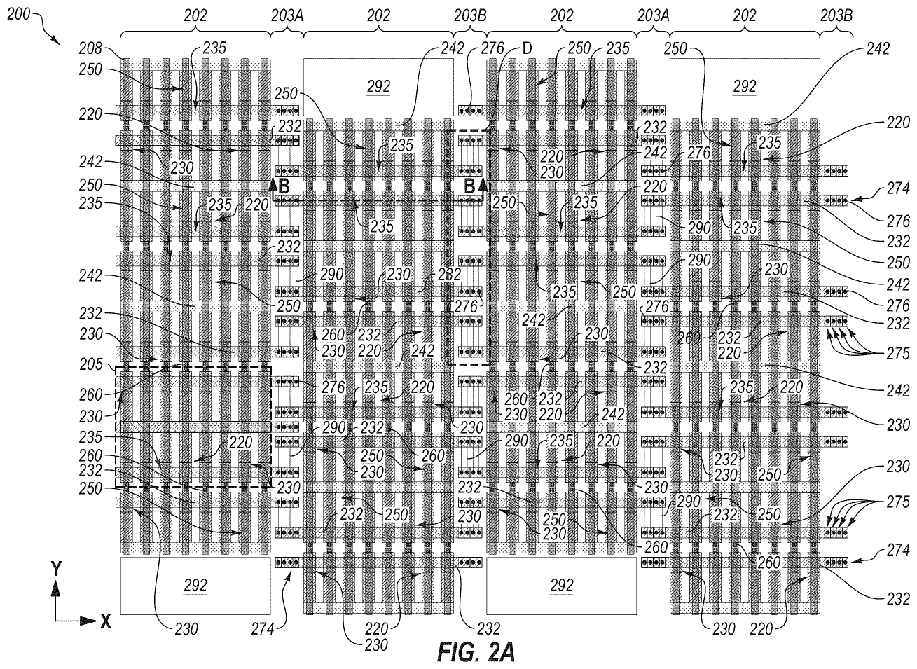

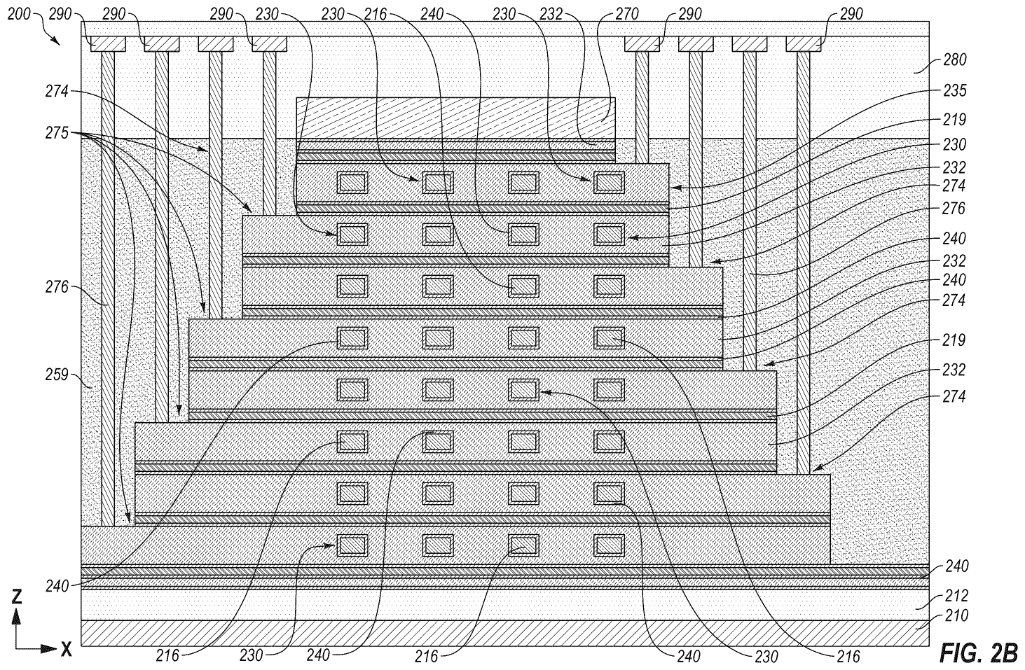

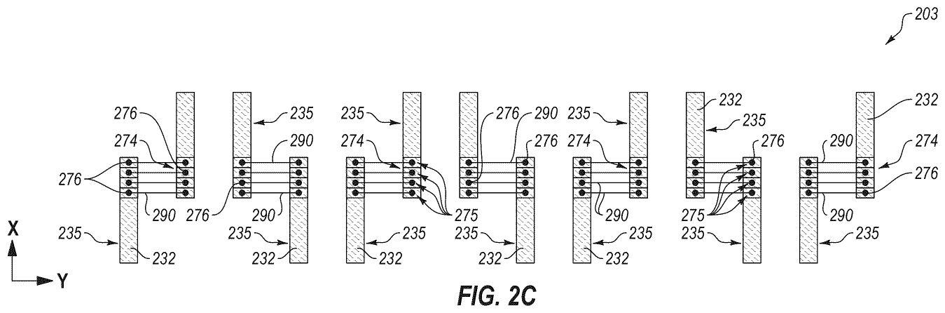

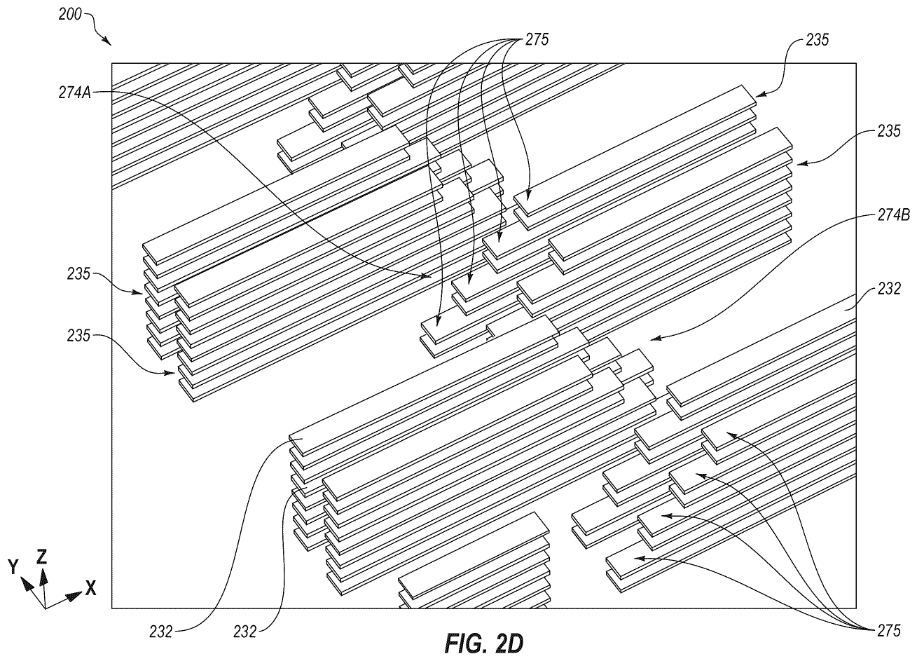

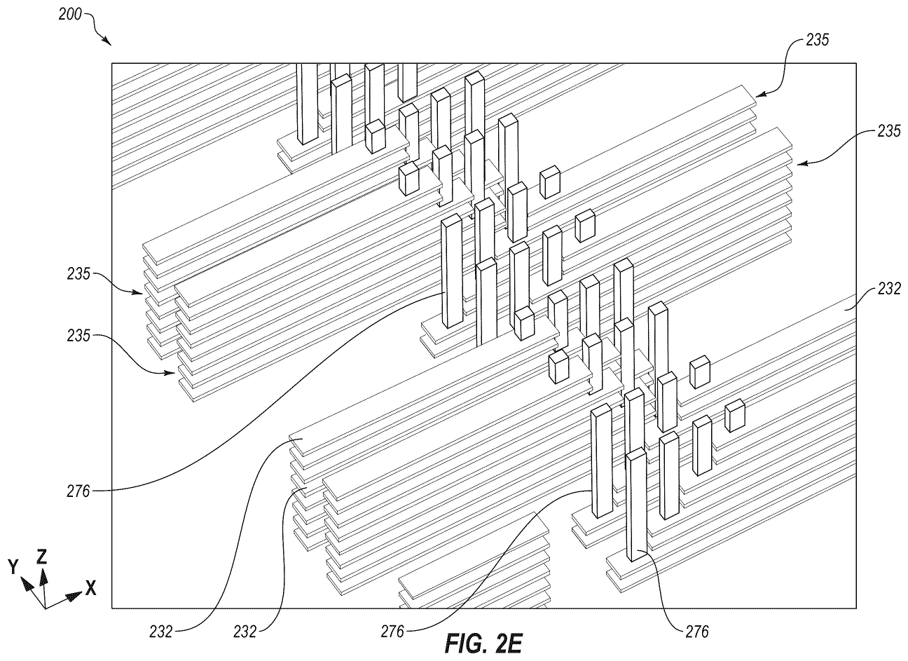

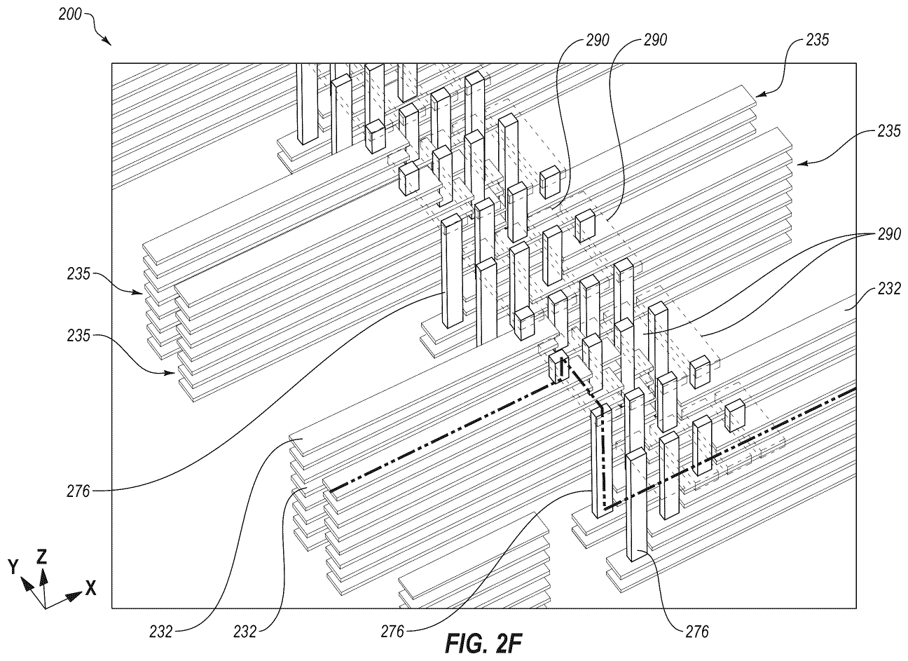

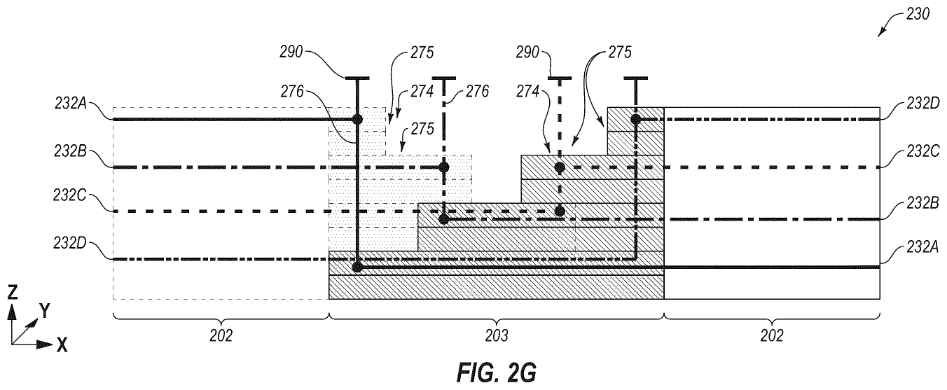

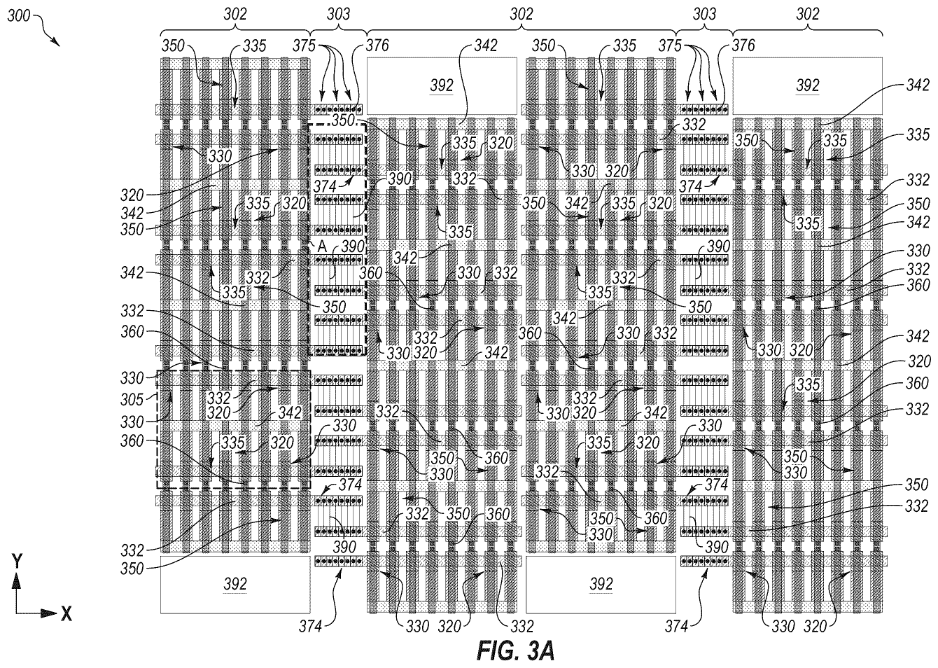

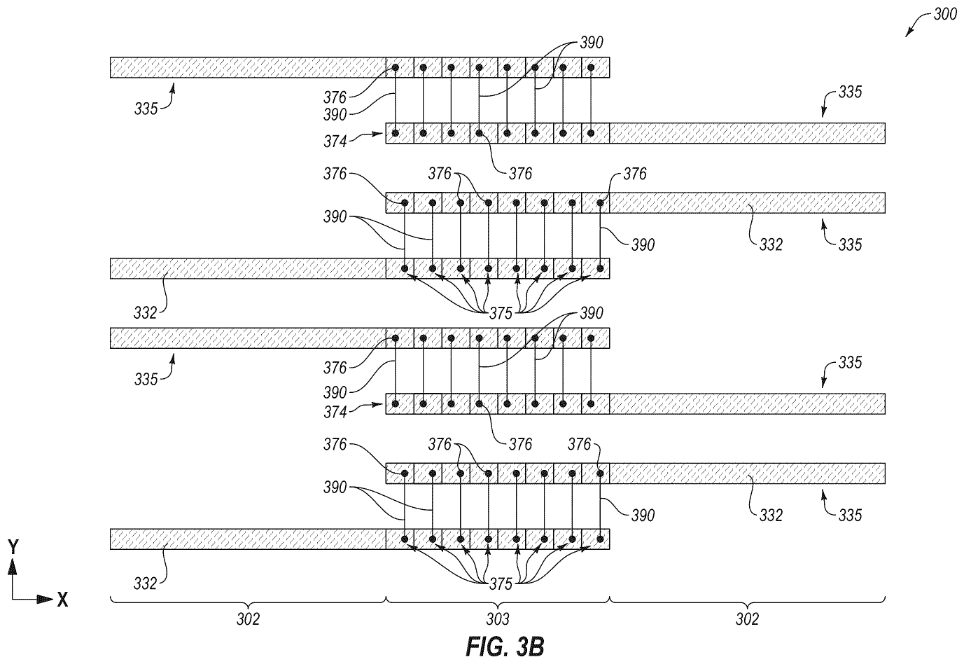

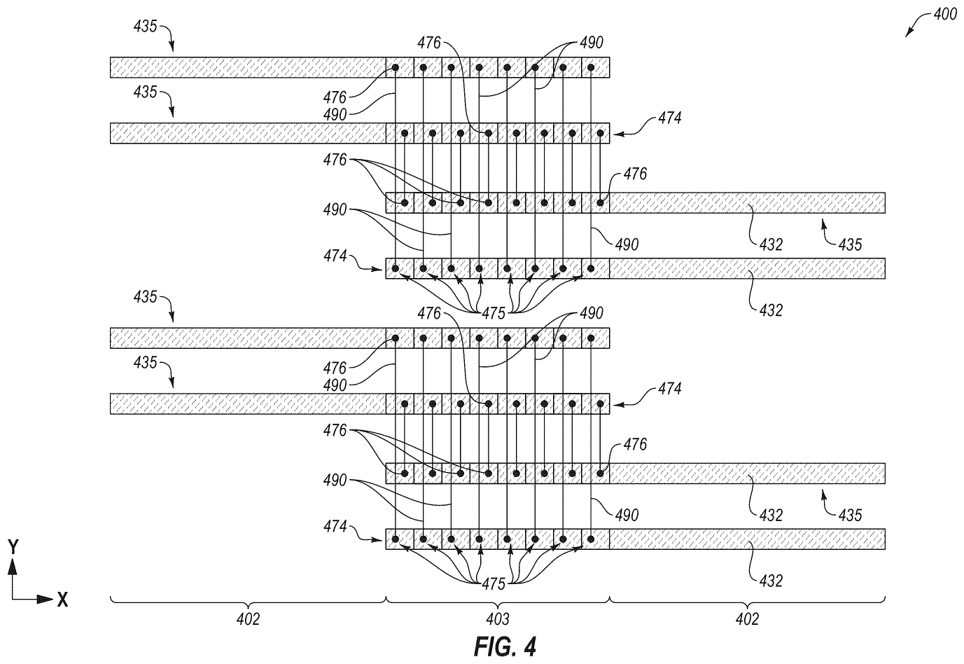

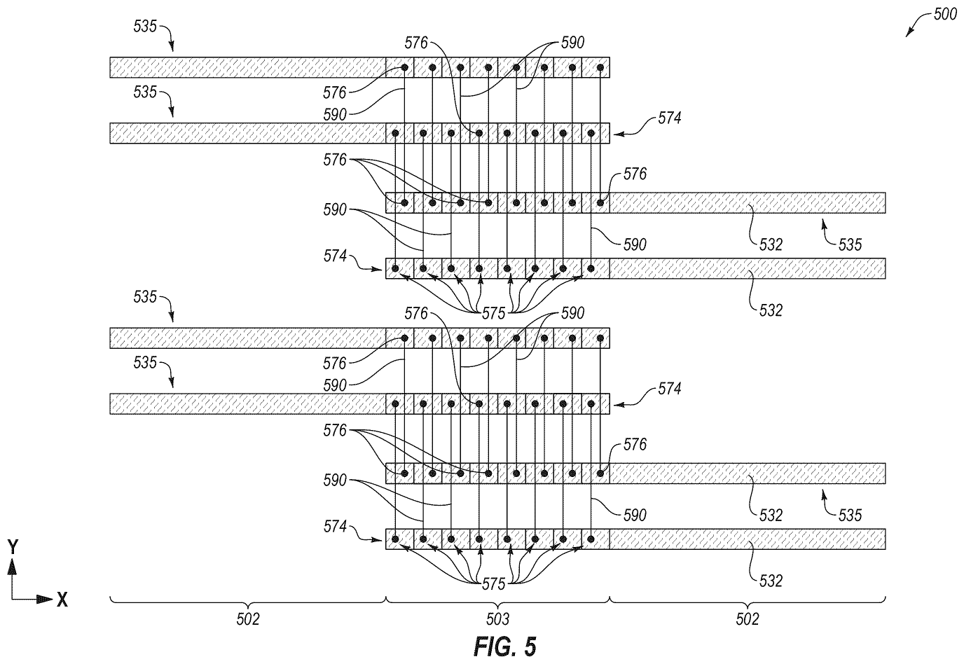

While the microelectronic device of FIG. 1A through FIG. 1H has been described and illustrated as having staircase regions 103 including staircase structures 174 having a particular orientation with respect to one another, the disclosure is not so limited. In additional embodiments, the microelectronic device 100 may be formed to have a different configuration than that previously described with reference to FIG. 1A through FIG. 1G. The microelectronic device 100 may, for example, be formed to exhibit a configuration such as one of the configurations depicted in FIG. 2A through FIG. 2F; FIG. 3A and FIG. 3B; FIG. 4; and FIG. 5, and described in further detail below. With the description provided below, it will be readily apparent to one of ordinary skill in the art that the structures and devices described herein may be included in relatively larger structures, devices, and systems.

Before turning to FIG. 2A, it will be understood that throughout FIG. 2A through FIG. 5 and the associated description, features (e.g., regions, materials, structures, devices) functionally similar to previously described features (e.g., previously described materials, structures, devices) are referred to with similar reference numerals incremented by 100. To avoid repetition, not all features shown in FIG. 2A through FIG. 5 are described in detail herein. Rather, unless described otherwise below, a feature in one or more of FIG. 2A through FIG. 5 designated by a reference numeral that is a 100 increment of the reference numeral of a feature previously described with reference to one or more of FIG. 1A through FIG. 1H will be understood to be substantially similar to and have substantially the same advantages as the previously described feature. In addition, unless described otherwise below, a feature in one or more of FIG. 3A through FIG. 5 designated by a reference numeral that is a 100 increment of the reference numeral of a feature previously described with reference to a preceding one or more of FIG. 2A through FIG. 4 will be understood to be substantially similar to and have substantially the same advantages as the previously described feature. As a non-limiting example, unless described otherwise below, features designated by the reference numerals 290, 390, 490, and 590 in FIG. 2A through FIG. 2G; FIG. 3A and FIG. 3B; FIG. 4; and FIG. 5, respectively, will be understood to respectively be substantially similar to and have substantially the same advantages as the lateral conductive contact 190 previously described herein with reference to FIG. 1A through FIG. 1H. In addition, for clarity and ease of understanding the drawings and related description, some features (e.g., structures, materials, regions, devices) previously described with reference to one or more of FIG. 1A through FIG. 1H are not depicted in FIG. 2A through FIG. 2G, FIG. 3A and FIG. 3B, FIG. 4, and FIG. 5. However, unless described otherwise below, it will be understood that any features of the microelectronic device 100 previously described with reference to FIG. 1A through FIG. 1H may be included in any of the different configurations described hereinbelow with reference to FIG. 2A through FIG. 2G, FIG. 3A and FIG. 3B, FIG. 4, and FIG. 5. As a non-limiting example, features substantially similar to the channel material 116 previously described with reference to FIG. 1B and FIG. 1C may be included in the different configurations described hereinbelow with reference to FIG. 2A through FIG. 2G, FIG. 3A and FIG. 3B, FIG. 4, and FIG. 5.

FIG. 2A is a simplified partial top-down view of a microelectronic device 200, in accordance with embodiments of the disclosure. FIG. 2B is a simplified partial cross-sectional view of the microelectronic device 200 of FIG. 2A taken through section line B-B. FIG. 2C is an enlarged portion of a portion of one of the staircase regions 203 and illustrating the vertical stack structure 235 of conductive structures 232 horizontally extending (e.g., in the X-direction) into the staircase region 203 and terminating at the respective staircase structures 274. FIG. 2D is a simplified perspective view illustrating box D of FIG. 2A, but not showing the lateral conductive contacts 290 or the conductive contact structures 276. FIG. 2E is a simplified perspective view illustrating the same view of FIG. 2D, but including the conductive contact structures 276 and not illustrating the lateral conductive contacts 290. FIG. 2F is a simplified perspective view illustrating the same view of FIG. 2D but including the conductive contact structures 276 and the lateral conductive contacts 290. For clarity and ease of understanding the description, the lateral conductive contacts 290 are illustrated in broken lines in FIG. 2F to illustrate the relative location of the lateral conductive contacts 290 with respect to the conductive contact structures 276 and the staircase structures 274. For clarity and ease of understanding the description, FIG. 2C through FIG. 2F do not illustrate other components of the microelectronic device 100, such as the vertical stacks of memory cells 120 within the array regions 202. FIG. 2G is a simplified schematic illustrating the electrical connections between horizontally neighboring staircase structures of the microelectronic device of FIG. 2A.

With reference to FIG. 2A, the microelectronic device 200 includes array regions 202 horizontally spaced (e.g., in the X-direction) from one another. The array regions 202 are substantially the same as the array regions 102 described above with reference to FIG. 1A and FIG. 1B. Staircase regions 203 including odd staircase regions 203A and even staircase regions 203B (collectively referred to as “staircase regions 203”) horizontally neighbor (e.g., in the X-direction) the array regions 202. In some embodiments, a staircase region 203 horizontally intervenes (e.g., in the X-direction) between horizontally neighboring (e.g., in the X-direction) array regions 202.

Horizontally neighboring (e.g., in the X-direction) array regions 202 may be horizontally offset (e.g., in the Y-direction) from one another. For example, with reference to FIG. 2A, the conductive plate structures 242 of each of the array regions 202 may be horizontally offset (e.g., in the Y-direction) from the conductive plate structures 242 of a horizontally neighboring (e.g., in the X-direction) array region 202. In some embodiments, the sub-arrays 205 of horizontally neighboring (e.g., in the X-direction) array regions 202 are horizontally offset (e.g., in the Y-direction) from one another by about one-half a pitch (e.g., in the Y-direction) of the sub-arrays 205. In some embodiments, the conductive plate structures 242 of a first array region 202 horizontally intervenes (e.g., in the Y-direction) between vertical stack structures 235 (and the associated staircase structures 274 within the staircase region 203) of a horizontally neighboring (e.g., in the X-direction) second array region 202. For example, in some embodiments, the conductive plate structures 242 of the first array region 202 may be horizontally between (e.g., in the Y-direction) a first vertical stack structure 235 of a first sub-array 205 of a horizontally neighboring (e.g., in the X-direction) second array region 202 and a second vertical stack structure 235 of a second sub-array 205 of the second array region 202, the second sub-array 205 horizontally neighboring (e.g., in the Y-direction) the first sub-array 205. In some embodiments, the conductive plate structures 242 of each array region 202 are horizontally aligned (e.g., in the Y-direction) with the conductive pillar structures 260 of the horizontally neighboring (e.g., in the X-direction) array regions 202.

In some embodiments, the sub-arrays 205 of every other one of the array regions 202 (e.g., in the X-direction) are horizontally aligned (e.g., in the Y-direction) with one another. For example, the conductive plate structures 242 of every other one of the array regions 202 are horizontally aligned (e.g., in the Y-direction) with one another.

With reference to FIG. 2A through FIG. 2F, the vertical stack structures 235 including the conductive structures 232 horizontally extend (e.g., in the X-direction) through the array regions 202 and terminate in staircase regions 203 horizontally neighboring (e.g., in the X-direction) the array region 202 through which each individual vertical stack structure 235 horizontally extends, as described above with reference to the vertical stack structures 135. In some embodiments, each vertical stack structure 235 horizontally terminates (e.g., in the X-direction) at a staircase structure 274 at each horizontal end (e.g., in the X-direction) thereof. In some such embodiments, each vertical stack structure 235 includes two staircase structures 274 (e.g., one staircase structure 274 at each horizontal end of the vertical stack structure 235).

With continued reference to FIG. 2B, in some embodiments, vertically neighboring (e.g., in the Z-direction) steps 275 of a staircase structure 274 on a first horizontal side (e.g., in the X-direction) of a vertical stack structure 235 may be vertically offset (e.g., in the Z-direction) by two levels (e.g., two tiers) of the vertically alternating conductive structures 232 and the vertically intervening dielectric material 240 and second insulative material 219. In some such embodiments, the steps 275 of each staircase structure 274 are formed of every other conductive structure 232 of the vertical stack structure 235 and the steps 275 of staircase structures 274 at horizontally opposing ends (e.g., in the X-direction) of the same vertical stack structure 235 may be defined by conductive structures 232 that are vertically spaced (e.g., in the Z-direction) from one another by one level of a conductive structure 232 and the vertically intervening dielectric material 240 and second insulative material 219. For example, and with reference to FIG. 2B, the steps 275 of a first staircase structure 274 of a vertical stack structure 235 are vertically offset (e.g., in the Z-direction) from the steps 275 of a second staircase structure 274 of the vertical stack structure 235 located at an opposite horizontal end (e.g., in the X-direction) of the vertical stack structure 235 than the first staircase structure 274.

In some embodiments, every other conductive structure 232 of the staircase structures 274 may include a conductive contact structure 276 in contact therewith. In other words, every other conductive structure 232 of the staircase structures 274 may individually be in contact with a conductive contact structure 276. In some such embodiments, each vertical stack structure 235 may include one staircase structure 274 at each horizontal (e.g., in the X-direction) end thereof and each conductive structure 232 of a first staircase structure 274 at a first horizontal end of the vertical stack structures 235 not in contact with a conductive contact structure 276 (e.g., the vertically lower conductive structure 232 of the pair of conductive structures 232 defining the step 275) may individually be in contact with a conductive contact structure 276 at a second staircase structure 274 at a second, opposite horizontal end of the vertical stack structure 235.

In some embodiments, every other one of the staircase regions 203 comprises an odd staircase regions 203A and the other staircase regions 203 comprise even staircase regions 203B. In other words, an even staircase region 203B may horizontally intervene (e.g., in the X-direction) between horizontally neighboring (e.g., in the X-direction) odd staircase regions 203A; and an odd staircase region 203A may horizontally intervene (e.g., in the X-direction) between horizontally neighboring (e.g., in the X-direction) even staircase regions 203B. The steps 275 of the staircase structures 274 within the odd staircase regions 203A may comprise odd steps 275 and the steps 275 of the staircase structures 274 within the even staircase regions 203B may comprise even steps 275. In some embodiments, the steps 275 within the odd staircase regions 203A are vertically aligned (e.g., in the Z-direction) with one another and vertically offset (e.g., in the Z-direction) from the steps 275 of the even staircase regions 203B by one level of the vertically alternating conductive structures 232 and the vertically intervening dielectric material 240 and second insulative material 219.

As described above with reference to the staircase structures 174, each of the staircase structures 274 may exhibit a positive slope or a negative slope. In some embodiments, a phantom line extending from a top of each of half of the staircase structures 274 to a bottom of the staircase structures 274 may have a positive slope, and another phantom line extending from a top of the other half of the staircase structures 274 to a bottom of the staircase structures 274 may have a negative slope. For example, with reference to FIG. 2D, staircase structure 274A may exhibit a positive slope and staircase structure 274B may exhibit a negative slope. In some embodiments, the positive slope and the negative slope have the same (e.g., the positive slope may be X, and the negative slope may be −X, where X is a number corresponding to the change in the vertical dimension (e.g., in the Z-direction) divided by the change in the horizontal dimension (e.g., in the X-direction) of the staircase structure 274).

With reference to FIG. 2A and FIG. 2D through FIG. 2F, pairs of the staircase structures 274 horizontally extending (e.g., in the positive X-direction) away from a first array region 202 and within a first staircase region 203 horizontally neighboring (e.g., in the X-direction) the first array region 202 may exhibit the same slope (e.g., the same positive slope) as one another; and additional pairs of the staircase structures 274 horizontally extending (e.g., in the negative X-direction) away from a second, neighboring array region 202 and within the first staircase region 203 may exhibit the same slope as one another and a different slope (e.g., the same negative slope) than the pairs of the staircase structures 274. In addition, further pairs of the staircase structures 274 horizontally extending (e.g., in the negative X-direction) away from the first array region 202 into a second staircase region 203 on an opposite side of the first array region 202 than the first staircase region 203 may have a different slope than the pairs of the staircase structures 274. In some embodiments, the additional pairs of the staircase structures 274 and the further pairs of the staircase structures 274 have substantially the same slope as one another.

Staircase structures 274 horizontally extending (e.g., in the positive X-direction) into an individual staircase region 203 from vertical stack structures 235 of an array region 202 may exhibit substantially the same slope as one another. In some embodiments, an individual staircase structure 274 within an individual staircase region 203 is horizontally between (e.g., in the Y-direction) an additional staircase structure 274 exhibiting the same slope as the staircase structure 274 and a further staircase structure 274 exhibiting different (e.g., opposite) slope than the staircase structure 274.

With reference to FIG. 2A, FIG. 2C, and FIG. 2F, lateral conductive contacts 290 may horizontally extend (e.g., in the Y-direction) between the conductive contact structures 276 in contact with respective conductive structures 232 of horizontally neighboring (e.g., in the Y-direction) staircase structures 274 horizontally extending from (e.g., in the X-direction) different array regions 202. With reference to FIG. 2F, the lateral conductive contacts 290 share a conductive path with the conductive structures 232 defining the steps 275 by means of the conductive contact structures 276. In some embodiments, each lateral conductive contact 290 shares a conductive path (e.g., is in electrical communication) with the conductive structure 232 defining one step 275 of a first staircase structure 274 by way of a conductive contact structure 276 in contact with the conductive structure 232 defining the step 275 and a conductive path with another conductive structure 232 of another step 275 of a second staircase structure 274 extending from a different array region 202 than the first staircase structure 274 by means of a conductive contact structure 276 in contact with the another step 275. In some embodiments, each lateral conductive contact 290 shares a conductive path (e.g., is in electrical communication with) a conductive structure 232 defining a first step 275 of a first staircase structure 274 and a conductive structure 232 defining a second step 275 of a second staircase structure 274 having a different height than the first step 275.

In FIG. 2F, the electrical connections between a conductive structure 232 of a vertically uppermost (e.g., in the Z-direction) step 275 of a first staircase structures 274 and a conductive structure 232 of a vertically lowermost (e.g., in the Z-direction) step 275 of a horizontally neighboring (e.g., in the Y-direction) second staircase structure 274 by way of a lateral conductive contact 290 is illustrated in broken lines.

With reference to FIG. 2A, FIG. 2C, FIG. 2D, and FIG. 2E, in some embodiments, within each of the staircase regions 203, the steps 275 of horizontally neighboring (e.g., in the Y-direction) staircase structures 274 are horizontally aligned (e.g., in the X-direction). The lateral conductive contacts 290 may extend in a horizontal direction (e.g., in the Y-direction) between horizontally neighboring (e.g., in the Y-direction) staircase structures 274.

In some embodiments, each of the lateral conductive contacts 290 have substantially the same horizontal length (e.g., in the Y-direction) as one another and are located at substantially the same vertical elevation (e.g., in the Z-direction) as one another.

In some embodiments, the vertically highest (e.g., in the Z-direction) step 275 of a first staircase structure 274 sharing a lateral conductive contact 290 with a second staircase structure 274 is laterally aligned (e.g., in the X-direction) with a vertically lowest (e.g., in the Z-direction) step 275 of the second staircase structure 274. A second vertically highest (e.g., in the Z-direction) step 275 of the first staircase structure 274 is laterally aligned (e.g., in the X-direction) with the second vertically lowermost (e.g., in the Z-direction) step 275 of the second staircase structure 274. The lateral alignment (e.g., in the X-direction) of the steps 275 of the first staircase structure 274 and the second staircase structure 274 continues such that a vertically lowermost (e.g., in the Z-direction) step 275 of the first staircase structure 274 is horizontally aligned (e.g., in the X-direction) with a vertically highest (e.g., in the Z-direction) step 275 of the second staircase structure 274, as described above with reference to the horizontal alignment of the steps 175 of the staircase structures 174 (FIG. 1A, FIG. 1D through FIG. 1G).

FIG. 2G is a simplified schematic illustrating the electrical connections between conductive structures 232 defining horizontally neighboring (e.g., in the Y-direction) staircase structures 274 of horizontally neighboring (e.g., in the X-direction) sub-arrays 205. In the view of FIG. 2G, the Y-direction is in and out of the page. In FIG. 2G, a first staircase structure 274 is illustrated in broken lines (e.g., the staircase structure 274 on the left) to indicate that it is located in a different plane than a second staircase structure 274. The conductive structures 232A, 232B, 232C, 232D defining the steps 275 of a first staircase structure 274 share a conductive path with the conductive structures 232A, 232B, 232C, 232D defining the step 275 of corresponding and horizontally aligned (e.g., in the X-direction) second staircase structure 274 by way of the lateral conductive contacts 290. FIG. 2G illustrates how the conductive structures 232A, 232B, 232C, 232D of a first staircase structure 274 individually share a conductive path (e.g., are in electrical communication with) corresponding conductive structures 232A, 232B, 232C, 232D of the second staircase structure 274 based on the vertical height (e.g., in the Z-direction) of the conductive structures 232A, 232B, 232C, 232D of each staircase structure 274.

In some embodiments, arranging the staircase regions 203 to include the odd staircase structures 274 and the even staircase structures 274; forming the staircase structures 274 to individually include one of even steps 275 or odd steps 275; and forming the lateral conductive contacts 290 between staircase structures 274 of different sub-arrays 205 of different array regions 202 facilitates reducing the horizontal dimension (e.g., in the X-direction) of the staircase regions 203. Accordingly, the arrangement of the staircase regions 203 in the microelectronic device 200 may reduce the area occupied by the staircase structures 274 and the staircase regions 203, facilitating an increase in the density of vertical stacks of memory cells 220 compared to conventional microelectronic devices.

With reference back to FIG. 2A, the array regions 202 may include additional regions 292 for placing one or more passive devices, such as charge pumps or passive capacitor devices.

FIG. 3A is a simplified top-down view a microelectronic device 300, in accordance with embodiments of the disclosure. FIG. 3B is a simplified top-down view illustrating a portion of a staircase region 303 of the microelectronic device 300 of FIG. 3A. The microelectronic device 300 may be substantially similar to the microelectronic device 200 of FIG. 2A through FIG. 2G, except that the staircase regions 303 may be different than the staircase regions 203.

With reference to FIG. 3A, the staircase regions 303 may horizontally intervene (e.g., in the X-direction) between some of the horizontally neighboring (e.g., in the X-direction) array regions 302 and may not horizontally intervene (e.g., in the X-direction) between other horizontally neighboring (e.g., in the X-direction) array regions 302. In some embodiments, the array regions 302 are individually horizontally neighbored (e.g., in the X-direction) by another array region 302 on a first horizontal side (e.g., in the X-direction) thereof and a staircase region 303 on a second, opposite horizontal side (e.g., in the X-direction) thereof. In some such embodiments, the array regions 302 may individually horizontally neighbor (e.g., in the X-direction) one staircase region 303 and one additional array region 302.

The staircase regions 303 may each individually include staircase structures 374 horizontally extending (e.g., in the X-direction) in the staircase region 303 extending from vertical stack structures 335 of respective array regions 302. Each staircase structure 374 may be operatively associated with and extend from a vertical stack structure 335 of conductive structures 332 horizontally extending (e.g., in the X-direction) through the array region 302. In some embodiments, some of the staircase structures 374 (e.g., half of the staircase structures 374) within a staircase region 303 are operatively associated with vertical stack structures 335 horizontally extending (e.g., in the X-direction) within a first array region 302 horizontally neighboring (e.g., in the X-direction) the staircase region 303 and other staircase structures 374 (e.g., the other half of the staircase structures 374) within the staircase region 303 are operatively associated with vertical stack structures 335 horizontally extending (e.g., in the X-direction) within a second array region 302 horizontally neighboring (e.g., in X-direction) the staircase region 303 opposite the first array region 302.

In some embodiments, each staircase structure 374 is horizontally between (e.g., in the Y-direction) a first staircase structure 374 associated with a vertical stack structures 335 from the same array region 302 (and a different sub-array 305) and horizontally neighboring (e.g., in the Y-direction) the staircase structure 374 in a first direction; and a second staircase structure 374 associated with a vertical stack structure 335 horizontally extending from a different array region 302 (and a different sub-array 305) and horizontally neighboring (e.g., in the Y-direction) the staircase structure 374 in a second direction.

FIG. 3B is an enlarged view of the portion of a staircase region 303 illustrated in box A of FIG. 3A. FIG. 3B illustrates the conductive contact structures 376 vertically over (e.g., in the Z-direction) the steps 375 and illustrates the relative positions of the conductive contact structures 376 on the steps 375, as well as the relative positions of the lateral conductive contacts 390. For clarity and ease of understanding the description, FIG. 3B does not illustrate portions of the array regions 302, such as the vertical stacks of memory cells (e.g., memory cells 120, 220). For example, within the array regions 302, FIG. 3B illustrates only the vertical stack structures 335 of the conductive structures 332 to show the relationship between the vertical stack structures 335 and the staircase structures 374 within the staircase region 303.

With reference to FIG. 3A and FIG. 3B, each of the steps 375 of the staircase structures 374 within a staircase region 303 are horizontally aligned (e.g., in the X-direction) with one another. For example, steps 375 of the staircase structures 374 may be horizontally aligned (e.g., in the X-direction) with one another and horizontally aligned (e.g., in the X-direction) with the conductive structures 332 of a horizontally neighboring (e.g., in the X-direction) array region 302 defining vertically lowermost (e.g., in the Z-direction) steps 375 of staircase structures 374 associated with the horizontally neighboring array region 302.

With reference to FIG. 3A and FIG. 3B, each of the steps 375 of the staircase structures 374 within a staircase region 303 are horizontally aligned (e.g., in the X-direction) with one another. For example, the vertically uppermost (e.g., in the Z-direction) step 375 of the staircase structures 374 associated with vertical stack structures 335 horizontally extending (e.g., in the X-direction) from the same array region 302 may be horizontally aligned (e.g., in the X-direction) with one another and horizontally aligned (e.g., in the X-direction) with the vertically lowermost (e.g., in the Z-direction) steps 375 of staircase structures 374 associated with vertical stack structures 335 horizontally extending (e.g., in the X-direction) from a horizontally neighboring (e.g., in the X-direction) array region 302.

Similarly, in some embodiments, at least some of the lateral conductive contacts 390 are horizontally aligned (e.g., in the X-direction) with one another and horizontally offset (e.g., in the X-direction) from other lateral conductive contacts 390. In some embodiments, about one half of the lateral conductive contacts 390 are horizontally offset (e.g., in the X-direction) from the other about one half of the lateral conductive contacts 390. The other about one half of the lateral conductive contacts 390 may be horizontally aligned (e.g., in the X-direction) with one another.

In some embodiments, the conductive contact structures 376 are individually laterally offset (e.g., in the X-direction) from a lateral center (e.g., in the X-direction) of the steps 375 which they vertically overlie (e.g., in the Z-direction) and to the conductive structures 332 of which they electrically connect. In some embodiments, the conductive contact structures 376 in contact with the conductive structures 332 defining a first staircase structure 374 may be located horizontally farther (e.g., in the X-direction) from a horizontal edge (e.g., in the X-direction) of a vertically neighboring upper (e.g., in the Z-direction) step 375 than to a horizontal edge (e.g., in the X-direction) of a vertically neighboring lower (e.g., in the Z-direction) step 375. The conductive contact structures 376 in contact with the conductive structures 332 of a first staircase structure 374 share a conductive path (e.g., be in electrical communication with) conductive contact structures 376 of the conductive structures 332 of a second staircase structure 374 by way of the lateral conductive contacts 390. The conductive contact structures 376 of the second staircase structure 374 may individually be located horizontally closer (e.g., in the X-direction) from a horizontal edge (e.g., in the X-direction) of a vertically neighboring upper (e.g., in the Z-direction) step 375 than to a horizontal edge (e.g., in the X-direction) of a vertically neighboring lower (e.g., in the Z-direction) step 375.

With continued reference to FIG. 3A and FIG. 3B, the lateral conductive contacts 390 horizontally extend (e.g., in the Y-direction) from the steps 375. The lateral conductive contacts 390 may electrically connect conductive contact structures 376 electrically connected to conductive structures 332 horizontally extending (e.g., in the X-direction) from different array regions 302 and operatively associated with different staircase structures 374. Each lateral conductive contact 390 may horizontally extend (e.g., in the Y-direction) from a first step 375 of a staircase structure 374 to a second step 375 of a horizontally neighboring (e.g., in the Y-direction) staircase structure 374 having a different vertical height (e.g., in the Z-direction) than the first step 375. In some embodiments, vertically higher (e.g., in the Z-direction) steps 375 share a conductive path (e.g., are in electrical communication) with vertically lower (e.g., in the Z-direction) steps 375 of other staircase structures 374 by means of the lateral conductive contacts 390. In other words, vertically higher steps 375 of each staircase structures 374 are in electrical communication with vertically lower (e.g., in the Z-direction) steps 375 of other staircase structures 374 by means of the lateral conductive contacts 390. In some embodiments, vertically higher (e.g., in the Z-direction) steps 375 of a first staircase structure 374 are in electrical communication with vertically lower (e.g., in the Z-direction) steps 375 of a second staircase structure 374 than steps 375 of the first staircase structure 374 having a height less than the height of the steps 375 of the first staircase structure 374.

In some embodiments, the lateral conductive contacts 390 horizontally extend (e.g., in the Y-direction) between horizontally neighboring (e.g., in the Y-direction) staircase structures 374 associated with vertical stack structures 335 horizontally extending (e.g., in the X-direction) from different array regions 302. The lateral conductive contacts 390 may horizontally extend from each staircase structures 374 to a horizontally nearest (e.g., in the Y-direction) staircase structure 374 associated with a different array region 302.

In some embodiments, the lateral conductive contacts 390 horizontally extending (e.g., in the Y-direction) from a first staircase structure 374 associated with a sub-array 305 within an array region 302 are horizontally offset (e.g., in the X-direction, in the Y-direction) from the lateral conductive contacts 390 horizontally extending (e.g., in the Y-direction) from a second staircase structure 374 associated with the same sub-array 305 of the array region 302.

Forming the microelectronic device 300 to include the staircase structures 374 and the lateral conductive contacts 390 facilitates reducing an area of the microelectronic device 300 occupied by the staircase regions 303 and the staircase structures 374 and increases the density of the memory cells 120.

FIG. 4 is a simplified top-down view of a portion of a microelectronic device 400, in accordance with embodiments of the disclosure. The microelectronic device 400 may be substantially similar to the microelectronic device 300 of FIG. 3A and FIG. 3B, except that the microelectronic device 400 may include one or more staircase regions 403 different than one or more of the staircase regions 303. The staircase region 403 may replace one or more of the staircase regions 303 of the microelectronic device 300 of FIG. 3A.

In some embodiments, the staircase structures 474 and the steps 475 may be horizontally aligned (e.g., in the X-direction) with one another, as described above with reference to the staircase structures 374 (FIG. 3A, FIG. 3B) and the steps 375 (FIG. 3A, FIG. 3B).

With reference to FIG. 4, some of the lateral conductive contacts 490 horizontally extend (e.g., in the Y-direction) from a staircase region 474 to a staircase region 474 directly horizontally neighboring (e.g., in the Y-direction) the staircase region 474. Other lateral conductive contacts 490 horizontally extend (e.g., in the Y-direction) from a staircase region 474 to a staircase region 474 more distal from the staircase region 474 than other staircase regions 474. In some embodiments, the lateral conductive contacts 490 include a first group of lateral conductive contacts 490 having a greater dimension (e.g., length) in the horizontal direction (e.g., the Y-direction) than lateral conductive contacts 490 of a second group of lateral conductive contacts 490.

In some embodiments, arranging the lateral conductive contacts 490 as illustrated in FIG. 4 facilitates activation of the conductive pillar structures 360 (FIG. 3A) of an array region 302 through which a vertical stack structure 335 horizontally extends (e.g., in the X-direction) without activating undesired conductive pillar structures 360 of other array regions 302. In some embodiments, each of the conductive pillar structures 360 of a particular array region 302 includes only one corresponding conductive pillar structure 360 in neighboring array region 302 and are activated simultaneously upon placement of a voltage to one or more of the lateral conductive contacts 490 shared by the steps 475 of the staircase structures 474 of the respective conductive pillar structures 360. Such an arrangement facilitates reducing a complexity of multiplexers associated with the conductive pillar structures 360.

FIG. 5 is a simplified top-down view of a portion of a microelectronic device 500, in accordance with embodiments of the disclosure. The microelectronic device 500 may be substantially similar to the microelectronic device 300 of FIG. 3A and FIG. 3B, except that the microelectronic device 400 may include one or more staircase regions 503 different than one or more of the staircase regions 303.

In some embodiments, the staircase structures 574 and the steps 575 may be horizontally aligned (e.g., in the X-direction) with one another, as described above with reference to the staircase structures 374 (FIG. 3A, FIG. 3B) and the steps 375 (FIG. 3A, FIG. 3B).

With reference to FIG. 5, each of the lateral conductive contacts 590 horizontally extending (e.g., in the Y-direction) from an individual staircase structure 574 horizontally extend to an additional staircase structure 574 spaced from the staircase structure 574 by a further additional staircase structure 574. In other words, the conductive contact structures 576 associated with every other one (e.g., in the Y-direction) of the staircase structures 574 are configured to be in electrical communication with each other by means of the lateral conductive contacts 590. In some embodiments, each of the lateral conductive contacts 590 is electrically connected to conductive contact structures 576 associated with every other one of the staircase structures 574.

In some embodiments, arranging the lateral conductive contacts 590 such that they horizontally extend (e.g., in the Y-direction) to the conductive contact structures 576 associated with every other one of the staircase structure 574 facilitates forming the lateral conductive contacts 590 to exhibit a substantially similar length. In some embodiments, each of the lateral conductive contacts 590 have about the same length. In some embodiments, each of the lateral conductive contacts 590 exhibits about the same resistivity.

Although the microelectronic devices 100, 200, 300, 400, 500 of FIG. 1A through FIG. 5 have been described and illustrated as including sub-arrays 105, 205, 305 including memory cells 120, 220, 320 having a particular configuration, the disclosure is not so limited. In other embodiments, the sub-arrays 105, 205, 305 may be different than those described above. For example, although the conductive structures 132, 232, 332, 432, 532 (e.g., the word lines) configured to be in electrical communication with the memory cells 120, 220, 320 (e.g., in electrical communication with the access devices 130, 230, 330) have been described and illustrated as horizontally extending (e.g., in the Y-direction) through the array regions 102, 202, 302 and terminate at the staircase structures 174, 274, 374, 474, 574; and the conductive pillar structures 160, 260, 360 (e.g., the local digit lines) vertically extending (e.g., in the Z-direction) and configured to be in electrical communication with the access devices 130, 230, 330, the disclosure is not so limited. In other embodiments, the word lines vertically extend (e.g., in the Z-direction) through the vertical stacks of memory cells 120, 220, 320 and are configured to be in electrical communication with the memory cells 120, 220, 320 (e.g., in electrical communication with the access devices 130, 230, 330); and the local digit lines horizontally extend (e.g., in the Y-direction) through the through the array regions and terminate at the staircase structures and are configured to be in electrical communication with the memory cells 120, 220, 320 (e.g., in electrical communication with the access devices 130, 230, 330).

Thus, in accordance with some embodiments, a microelectronic device comprises memory array regions individually comprising a vertical stack of memory cells comprising a vertical stack of access devices and a vertical stack of capacitors horizontally neighboring the vertical stack of access devices. The memory array regions further comprise a vertical stack structure comprising conductive structures vertically spaced from one another and horizontally extending through the vertical stack of memory cells, the conductive structures neighboring the access devices of the vertical stack of access devices. A staircase region is horizontally between two of the memory array regions horizontally neighboring one another and comprises a first staircase structure horizontally extending from the vertical stack structure of a first of the two of the memory array regions and comprising first steps at horizontal edges of the conductive structures of the vertical stack structure of the first of the two of the memory array regions, a second staircase structure horizontally extending from the vertical stack structure of a second of the two of the memory array regions and comprising second steps at horizontal edges of the conductive structures of the vertical stack structure of the first of the two of the memory array regions, and lateral conductive contacts providing a conductive path between the first steps of the first staircase structure and the second steps of the second staircase structure.

Furthermore, in accordance with additional embodiments of the disclosure, a microelectronic device comprises a memory array bank comprising a first memory array and a second memory array. The first memory array and the second memory array individually comprise vertical stacks of dynamic random access memory (DRAM) cells, each DRAM cell comprising a storage device horizontally neighboring an access device, and a vertical stack structure comprising vertically spaced conductive structures horizontally extending through the vertical stacks of DRAM cells, the conductive structures of the vertical stack structure neighboring the DRAM cells of the vertical stacks of DRAM cells. The microelectronic device further comprises a staircase region horizontally between the first memory array and the second memory array. The staircase region comprises a first staircase structure horizontally extending from the vertical stack structure of the first memory array, a second staircase structure horizontally extending from the vertical stack structure of the second memory array, and lateral conductive contacts horizontally extending from the first staircase structure to the second staircase structure, each lateral conductive contact operably coupled to one step of the first staircase structure and one step of the second staircase structure.

Moreover, in accordance with some embodiments of the disclosure, a memory device comprises a first memory array region comprising first vertical stacks of first dynamic random access memory (DRAM) cells, each of the first DRAM cells comprising a storage device of a vertical stack of storage devices and a horizontally neighboring access device of a vertical stack of access devices, a first vertical stack structure comprising vertically spaced first conductive structures horizontally extending through the first memory array region and terminating at a first staircase structure in a staircase region horizontally neighboring the first memory array region, a second memory array region comprising second vertical stacks of second DRAM cells, a second vertical stack structure comprising second vertically spaced conductive structures horizontally extending through the second memory array region and terminating at a second staircase structure in the staircase region, and lateral conductive contacts electrically connecting steps of the first staircase structure to steps of the second staircase structure.

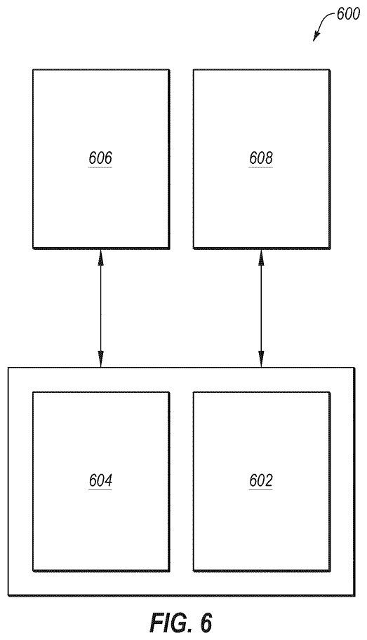

Structures, assemblies, and devices in accordance with embodiments of the disclosure may be included in electronic systems of the disclosure. For example, FIG. 6 is a block diagram of an illustrative electronic system 600 according to embodiments of disclosure. The electronic system 600 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 600 includes at least one memory device 602. The memory device 602 may comprise, for example, an embodiment of one or more microelectronic devices previously described herein with reference to FIG. 1A through FIG. 5. The electronic system 600 may further include at least one electronic signal processor device 604 (often referred to as a “microprocessor”). The electronic signal processor device 604 may, optionally, include an embodiment of one or more microelectronic devices previously described herein with reference to FIG. 1A through FIG. 5. While the memory device 602 and the electronic signal processor device 604 are depicted as two (2) separate devices in FIG. 6, in additional embodiments, a single (e.g., only one) memory/processor device having the functionalities of the memory device 602 and the electronic signal processor device 604 is included in the electronic system 600. In such embodiments, the memory/processor device may include one or more microelectronic devices previously described herein with reference to FIG. 1A through FIG. 5. The electronic system 600 may further include one or more input devices 606 for inputting information into the electronic system 600 by a user, such as, for example, a mouse or other pointing device, a keyboard, a touchpad, a button, or a control panel. The electronic system 600 may further include one or more output devices 608 for outputting information (e.g., visual or audio output) to a user such as, for example, one or more of a monitor, a display, a printer, an audio output jack, and a speaker. In some embodiments, the input device 606 and the output device 608 may comprise a single touchscreen device that can be used both to input information to the electronic system 600 and to output visual information to a user. The input device 606 and the output device 608 may communicate electrically with one or more of the memory device 602 and the electronic signal processor device 604.

Thus, in accordance with embodiments of the disclosure, an electronic system comprises an input device, an output device, a processor device operably coupled to the input device and the output device, and a memory device operably coupled to the processor device. The memory device comprises a first array region comprising vertical stacks of memory cells, each memory cell comprising a capacitor device and an access device coupled to the capacitor device, a first vertical stack of first conductive structures vertical spaced from another and horizontally extending in a first horizontal direction through the first array region, the first conductive structures horizontally terminating at a staircase structure in a staircase region horizontally neighboring the first array region, a second array region horizontally spaced from the first array region in the first horizontal direction, the second array region comprising additional vertical stacks of memory cells, a second vertical stack of second conductive structures vertical spaced from another and horizontally extending in the first horizontal direction through the second array region, the second conductive structures horizontally terminating at a second staircase structure in the staircase region, and lateral conductive contacts horizontally extending in a second horizontal direction between a first staircase structure and the second staircase structure and operably coupled to steps of the first staircase structure and steps of the second staircase structure.

The materials described herein may be formed by conventional techniques including, but not limited to, spin coating, blanket coating, chemical vapor deposition (CVD), atomic layer deposition (ALD), plasma enhanced ALD, physical vapor deposition (PVD), plasma enhanced chemical vapor deposition (PECVD), or low pressure chemical vapor deposition (LPCVD). Alternatively, the materials may be grown in situ. Depending on the specific material to be formed, the technique for depositing or growing the material may be selected by a person of ordinary skill in the art. The removal of materials may be accomplished by any suitable technique including, but not limited to, etching, abrasive planarization (e.g., chemical-mechanical planarization), or other known methods unless the context indicates otherwise.

As used herein, the term “configured” refers to a size, shape, material composition, orientation, and arrangement of one or more of at least one structure and at least one apparatus facilitating operation of one or more of the structure and the apparatus in a predetermined way.

As used herein, the terms “longitudinal,” “vertical,” “lateral,” and “horizontal” are in reference to a major plane of a substrate (e.g., base material, base structure, base construction, etc.) in or on which one or more structures and/or features are formed and are not necessarily defined by Earth's gravitational field. A “lateral” or “horizontal” direction is a direction that is substantially parallel to the major plane of the substrate, while a “longitudinal” or “vertical” direction is a direction that is substantially perpendicular to the major plane of the substrate. The major plane of the substrate is defined by a surface of the substrate having a relatively large area compared to other surfaces of the substrate. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped, etc.) and the spatially relative descriptors used herein interpreted accordingly.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, the term “memory device” means and includes microelectronic devices exhibiting memory functionality, but not necessarily limited to memory functionality. Stated another way, and by way of example only, the term “memory device” means and includes not only conventional memory (e.g., conventional volatile memory, such as conventional DRAM; conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pa), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively doped polysilicon, conductively doped germanium (Ge), conductively doped silicon germanium (SiGe)). In addition, a “conductive structure” means and includes a structure formed of and including a conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including an insulative material.

As used herein, “semiconductor material” or “semiconductive material” refers to a material having an electrical conductivity between those of insulative materials and conductive materials. For example, a semiconductor material may have an electrical conductivity of between about 10-8 Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

As used herein, the term “in electrical communication” when used with reference to a first component or structure with respect to a second component or structure means and includes that in use and operation, the first component or structure is configured to be electrically connected to the second component. By way of non-limiting example, when a first component is in electrical communication with a second component, in use and operation electrons flow between the first component and the second component, such as responsive to receipt of an input voltage (e.g., to the first component). A first component may be in electrical communication with a second component without directly contacting the second component; or may be in electrical communication with the second component by directly contacting the second component.

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modifications to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. A microelectronic device, comprising:
memory array regions individually comprising:
a vertical stack of memory cells, comprising:
a vertical stack of access devices; and
a vertical stack of capacitors horizontally neighboring the vertical stack of access devices; and
a vertical stack structure comprising conductive structures vertically spaced from one another and horizontally extending through the vertical stack of memory cells, the conductive structures neighboring the memory cells of the vertical stack of memory cells;
a staircase region horizontally between two of the memory array regions horizontally neighboring one another, the staircase region comprising:
a first staircase structure horizontally extending from the vertical stack structure of a first of the two of the memory array regions and comprising first steps at horizontal edges of the conductive structures of the vertical stack structure of the first of the two of the memory array regions;
a second staircase structure horizontally extending from the vertical stack structure of a second of the two of the memory array regions and comprising second steps at horizontal edges of the conductive structures of the vertical stack structure of the first of the two of the memory array regions; and
lateral conductive contacts providing a conductive path between the first steps of the first staircase structure and the second steps of the second staircase structure.

2. The microelectronic device of claim 1, wherein a vertically uppermost one of the first steps of the first staircase structure shares a conductive path with a vertically lowermost one of the second steps of the second staircase structure by means of one of the lateral conductive contacts.

3. The microelectronic device of claim 1, wherein:
the vertical stack structure of the first of the two of the memory array regions extends in a first horizontal direction; and
the first staircase structure horizontally neighbors the second staircase structure in a second horizontal direction orthogonal to the first horizontal direction.

4. The microelectronic device of claim 3, wherein the first steps of the first staircase structure horizontally overlap the second steps of the second staircase structure in the first horizontal direction.

5. The microelectronic device of claim 4, wherein:
an uppermost one of the first steps of the first staircase structure is substantially aligned with a lowermost one of the second steps of the second staircase structure in the first horizontal direction; and
an uppermost one of the second steps of the second staircase structure is substantially aligned with a lowermost one of the first steps of the first staircase structure in the first horizontal direction.

6. The microelectronic device of claim 1, wherein the first steps of the first staircase structure comprise every other one of the conductive structures of the vertical stack structure of the first of the two of the memory array regions.

7. The microelectronic device of claim 6, further comprising an additional staircase region comprising additional staircase structures horizontally extending from the vertical stack structure of the first of the two of the memory array regions and the vertical stack structure of the second of the two of the memory array regions, the additional staircase region horizontally spaced from the staircase region by one of the two of the memory array regions.

8. The microelectronic device of claim 1, wherein the vertical stack of memory cells of a first of the memory array regions is horizontally aligned with the vertical stack of memory cells of a second of the memory array regions.

9. The microelectronic device of claim 1, wherein the vertical stack of memory cells of a first of the memory array regions is horizontally offset from the vertical stack of memory cells of a second of the memory array regions in a horizontal direction in which the lateral conductive contacts extend.

10. The microelectronic device of claim 1, wherein the conductive structures of the vertical stack structure of the first of the two of the memory array regions comprise word lines configured to be electrical communication with access devices of the first of the two of the memory array regions.

11. The microelectronic device of claim 1, wherein the conductive structures of the vertical stack structure of the first of the two of the memory array regions comprise digit lines vertically overlying the access devices of the first of the two of the memory array regions.

12. A microelectronic device, comprising:
a memory array bank comprising a first memory array and a second memory array, the first memory array and the second memory array individually comprising:
vertical stacks of dynamic random access memory (DRAM) cells, each DRAM cell comprising a storage device horizontally neighboring an access device; and
a vertical stack structure comprising vertically spaced conductive structures horizontally extending through the vertical stacks of DRAM cells, the conductive structures of the vertical stack structure neighboring the DRAM cells of the vertical stacks of DRAM cells; and
a staircase region horizontally between the first memory array and the second memory array, the staircase region comprising:
a first staircase structure horizontally extending from the vertical stack structure of the first memory array;
a second staircase structure horizontally extending from the vertical stack structure of the second memory array; and
lateral conductive contacts horizontally extending from the first staircase structure to the second staircase structure, each lateral conductive contact operably coupled to one step of the first staircase structure and one step of the second staircase structure.

13. The microelectronic device of claim 12, further comprising vertically extending word lines, each vertically extending word line vertically extending along sides of access devices of a vertical stack of DRAM cells of the vertical stacks of DRAM cells.

14. The microelectronic device of claim 12, wherein a lower one half of the steps of the first staircase structure horizontally overlap with a lower one half of the steps of the second staircase structure.

15. The microelectronic device of claim 12, further comprising additional lateral conductive contacts horizontally extending between a third staircase structure extending from an additional vertical stack structure of the first memory array and a fourth staircase structure horizontally extending from an additional vertical stack structure of the second memory array.

16. A memory device, comprising:
a first memory array region comprising first vertical stacks of first dynamic random access memory (DRAM) cells, each of the first DRAM cells comprising a storage device of a vertical stack of storage devices and a horizontally neighboring access device of a vertical stack of access devices;
a first vertical stack structure comprising vertically spaced first conductive structures horizontally extending through the first memory array region and terminating at a first staircase structure in a staircase region horizontally neighboring the first memory array region;
a second memory array region comprising second vertical stacks of second DRAM cells;
a second vertical stack structure comprising second vertically spaced conductive structures horizontally extending through the second memory array region and terminating at a second staircase structure in the staircase region; and
lateral conductive contacts electrically connecting steps of the first staircase structure to steps of the second staircase structure.

17. The memory device of claim 16, wherein the staircase region horizontally intervenes between the first memory array region and the second memory array region.

18. The memory device of claim 16, wherein:
the first memory array region is horizontally spaced from the second memory array region in a first horizontal direction; and
the lateral conductive contacts horizontally extend in a second horizontal direction orthogonal to the first horizontal direction.

19. The memory device of claim 16, wherein the first DRAM cells are horizontally offset from the second DRAM cells in a first horizontal direction and a second horizontal direction.

20. The memory device of claim 16, further comprising conductive contact structures individually in contact with the steps of the first staircase structure and the steps of the second staircase structure, the lateral conductive contacts in contact with the conductive contact structures.
